(19) United States
(12) Patent Application Publication
(10) Pub. No.: US 2022/0402134 A1
(43) Pub. Date: Dec. 22, 2022

(54) USING SIMULATED/GENERATED NOISE TO EVALUATE AND REFINE STATE ESTIMATION

(71) Applicant: Dexterity, Inc., Redwood City, CA (US)

(72) Inventors: Rohit Arka Pidaparthi, Mountain View, CA (US); William Arthur Clary, Palo Alto, CA (US); Neeraja Abhyankar, Menlo Park, CA (US); Jonathan Kuck, Palo Alto, CA (US); Ben Varkey Benjamin Pottayil, Foster City, CA (US); Kevin Jose Chavez, Redwood City, CA (US); Shitij Kumar, Redwood City, CA (US)

(21) Appl. No.: 17/838,034

(22) Filed: Jun. 10, 2022

Related U.S. Application Data
(60) Provisional application No. 63/211,365, filed on Jun. 16, 2021.

(51) Int. Cl. B25J 9/16; B25J 13/08

(52) U.S. Cl. CPC B25J 9/1671; B25J 9/1687; B25J 9/1697; B25J 13/087

(57) ABSTRACT

A robotic system is disclosed. The system includes a memory configured to store estimated state information associated with a computer simulation of a robotic operation to stack a plurality of items on a pallet or other receptacle. The system includes one or more processors coupled to the communication interface and configured to perform the computer simulation. The computer simulation is performed at least in part by combining geometric model data based on idealized simulated robotic placement of each item with programmatically generated noise data. The programmatically generated noise data reflects an estimation of the effect that one or more sources of noise in a real-world physical workspace with which the computer simulation is associated would have on a real-world state of the plurality of items and/or the pallet or other receptacle if the plurality of items were stacked on the pallet or other receptacle as simulated in the computer simulation.

### CROSS REFERENCE TO OTHER APPLICATIONS

This application claims priority to U.S. Provisional Patent Application No. 63/211,365 entitled USING SIMULATED/GENERATED NOISE TO EVALUATE AND REFINE STATE ESTIMATION filed Jun. 16, 2021 which is incorporated herein by reference for all purposes.

### BACKGROUND OF THE INVENTION

Shipping and distribution centers, warehouses, shipping docks, air freight terminals, big box stores, and other activities that ship and receive non-homogeneous sets of items use strategies such as packing and unpacking dissimilar items in boxes, crates, containers, conveyor belts, and on pallets, etc. Packing dissimilar items in boxes, crates, on pallets, etc. enables the resulting sets of items to be handled by heavy lifting equipment, such as forklifts, cranes, etc., and enables items to be packed more efficiently for storage (e.g., in a warehouse) and/or shipment (e.g., in truck, cargo hold, etc.).

In some contexts, items may be so dissimilar in size, weight, density, bulkiness, rigidity, strength of packaging, etc. that any given item or set of items may or may not have attributes that would enable those items to support the size, weight, distribution of weight, etc., of a given other item that might be required to be packed (e.g., in a box, container, pallet, etc.). When assembling a pallet or other set of dissimilar items, items must be selected and stacked carefully to ensure the palletized stack does not collapse, lean, or otherwise become unstable (e.g., so as not to be able to be handled by equipment such as a forklift, etc.) and to avoid item damage.

Currently, pallets typically are stacked and/or unpacked by hand. Human workers select items to be stacked, e.g., based on a shipping invoice or manifest, etc., and use human judgment and intuition to select larger and heavier items to place on the bottom, for example. However, in some cases, items simply arrive via a conveyor or other mechanism and/or are selected from bins in an ordered list, etc., resulting in an unstable palletized or otherwise packed set.

Use of robotics is made more challenging in many environments due to the variety of items, variations in the order, number, and mix of items to be packed, on a given pallet for example, and a variety of types and locations of container and/or feed mechanisms from which items must be picked up to be placed on the pallet or other container.

### BRIEF DESCRIPTION OF THE DRAWINGS

Various embodiments of the invention are disclosed in the following detailed description and the accompanying drawings.

FIG. 1 is a diagram illustrating a robotic system to palletize and/or depalletize heterogeneous items according to various embodiments.

FIG. 2 is a diagram illustrating a robotic system to palletize and/or depalletize heterogeneous items according to various embodiments.

FIG. 3 is a flow chart illustrating a process to palletize one or more items according to various embodiments.

FIG. 4 is a flow chart illustrating a process to simulate movement of a set of items according to various embodiments.

FIG. 5 is a flow chart illustrating a process to simulate movement of a set of items according to various embodiments.

FIG. 6 is a flow chart illustrating a process to simulate movement of a set of items according to various embodiments.

FIG. 7A is a diagram of an idealized state using geometric data according to various embodiments.

FIG. 7B is a diagram of an idealized state using geometric data according to various embodiments.

FIG. 8 is a flow diagram illustrating an embodiment of determining an estimate of a state of a pallet and/or stack of items.

FIG. 9 is a flow diagram illustrating a process of determining an estimated state according to various embodiments.

FIG. 10 is a flow diagram illustrating a process of using an estimated state in connection with simulation of moving a set of items according to various embodiments.

FIG. 11 is a flow diagram illustrating a process of performing a simulation of moving a set of items according to various embodiments.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As used herein, a geometric model may mean a model of a state of a workspace such as a programmatically determined state. For example, the geometric model is generated using geometric data determined in connection with generating a plan to move an item in the workspace and an expected result if the item was moved according to plan. For example, a geometric model corresponds to a state of a workspace that is modified by controlling a robotic arm to pick, move, and/or place items within the workspace, and the picking, moving, and placing of the item is deemed to be performed according to plan (e.g., without error such as error or noise that may be introduced based on (i) a mis-configuration or mis-alignment of the robotic arm or another component in the workspace, (ii) a deforming of the item based on interaction with the robotic arm, (iii) another item in the workspace, another object in the workspace, (iv) a collision between the robotic arm, or item being moved by the robotic arm, and another object in the workspace, etc.).

As used herein, “pallet” includes a platform, receptacle, or other container on, or in, which one or more items may be stacked or placed. Further, as used herein, the pallet may be used in connection with packaging and distributing a set of one or more items. As an example, the term pallet includes the typical flat transport structure that supports items and that is movable via a forklift, a pallet jack, a crane, etc. A pallet, as used herein, may be constructed of various materials including, wood, metals, metal alloys, polymers, etc.

As used herein, palletization of an item or a set of items includes picking an item from a source location, such as a conveyance structure, and placing the item on a pallet such as on a stack of items on the pallet.

As used herein, depalletization includes picking an item from a pallet, such as from a stack of items on the pallet, moving the item, and placing the item at a destination location such as a conveyance structure. An example palletization/depalletization system and/or process for palletizing/de-palletizing a set of items is further described in U.S. patent application Ser. No. 17/343,609, the entirety of which is hereby incorporated herein for all purposes.

As used herein, singulation of an item includes picking an item from a source pile/flow and placing the item on a conveyance structure (e.g., a segmented conveyor or similar conveyance). Optionally, singulation may include sortation of the various items on the conveyance structure such as via singly placing the items from the source pile/flow into a slot or tray on the conveyor. An example of a singulation system and/or process for singulating a set of items is further described in U.S. patent application Ser. No. 17/246,356, the entirety of which is hereby incorporated herein for all purposes.

As used herein, kitting includes the picking of one or more items/objects from corresponding locations and placing the one or more items in a predetermined location in a manner that a set of the one or more items corresponds to a kit. An example of a kitting system and/or process for kitting a set of items is further described in U.S. patent application Ser. No. 17/219,503, the entirety of which is hereby incorporated herein for all purposes.

As used herein, a vision system includes one or more sensors that obtain sensor data, for example, sensor data pertaining to a workspace. Sensors may include one or more of a camera, a high-definition camera, a 2D camera, a 3D (e.g., RGBD) camera, an infrared (IR) sensor, other sensors to generate a three-dimensional view of a workspace (or part of a workspace such as a pallet and stack of items on the pallet), any combination of the foregoing, and/or a sensor array comprising a plurality of sensors of the foregoing, etc.

Techniques are disclosed to programmatically use a robotic system comprising one or more robots (e.g., a robotic arm with suction, gripper, and/or other end effector at operative end) to palletize/depalletize and/or to otherwise pack and/or unpack arbitrary sets of non-homogeneous items (e.g., dissimilar size, shape, weight, weight distribution, rigidity, fragility, type, packaging, etc.).

Various embodiments include a system, method, and/or device for (i) picking and placing items, (ii) for planning the placement of items, and/or (iii) determining/providing an estimated state of a workspace. The system includes a memory and one or more processors coupled to the memory. The memory is configured to store estimated state information associated with a computer simulation of a robotic operation to stack a plurality of items on a pallet or other receptacle. The one or more processors are configured to perform the computer simulation. The computer simulation is performed at least in part by combining geometric model data based on idealized simulated robotic placement of each item with programmatically generated noise data. The programmatically generated noise data reflects an estimation of the effect that one or more sources of noise in a real world physical workspace with which the computer simulation is associated would have on a real world state of one or both of the plurality of items and the pallet or other receptacle if the plurality of items were stacked on the pallet or other receptacle as simulated in the computer simulation.

Robotic systems may be implemented to assemble a pallet with items and/or disassemble a pallet of items. The robotic system may use sensors and a robot (e.g., a robotic arm comprising an end effector to engage an item). The items assembled on a pallet may be a heterogeneous set of items. The robotic system generally determines a plan for placing the set of items. For example, for each item, the robotic system generally determines a location (e.g., a destination location) on the pallet at which the item is to be placed. When determining where to place an item, a robotic system generally obtains sensor data directed to the pallet, or the stack of items on the pallet, and determines the location at which to place the item based on the sensor data.

The determining of where to place an item based on the sensor data may require a model of the state of a pallet or receptacle on which an item is placed and/or a model of a stack of items on the pallet or receptacle. The robotic system may obtain a model of the state based on the sensor data using a predefined state estimation module/method.

Some challenges arising from the development or use of a predefined state estimation module/model include:
Developing and/or determining effectiveness of a state estimation module/model includes simulating the physical palletization/depalletization of a set of items, obtaining sensor data in connection with the moving/placing of items. The moving of the set of items is resource intensive at least with respect to time and energy.
A state estimation module/model may be developed through an iterative improvement process of iteratively simulating the physical palletization/depalletization of a set of items and determining the effectiveness of a state estimation module/model such as via obtaining a measure(s) of performance (e.g., stability, density, time to complete, etc.) in the physical simulations the physical palletization/depalletization of a set of items. The measure of performance is obtained, for example, by obtaining sensor data using a vision system corresponding to the workspace of the robot performing the palletization/depalletization of a set of items.
Determining a state estimation module/model to implement in connection with the palletization/depalletization of a set of items may include evaluating a plurality of state estimation modules/models, and selecting the state estimation module/model to implement based on the evaluation (e.g., selecting the best state estimation module/model). Evaluation of the plurality of state estimation modules/models includes iteratively running physical simulations of the physical palletization/depalletization of a set of items, obtaining information pertaining to each simulation (e.g., a measure of performance in the physical simulations the physical palletization/depalletization of a set of items), and comparing different features/performance of the different state estimation modules/models.
Iterative physical simulation of the palletization/depalletization of the set of items is further complicated by the set of simulations be performed requiring different sets of items (e.g., a different types/collections of boxes, etc.), the set of simulations comprising different input item sequences, or the set of simulations comprising different item placement sequences, etc.

Related art systems that use physical simulation to develop a state estimation module/model is time and resource intensive. According to various embodiments, a state estimation module/model is developed using computer simulations of the picking/placing items (e.g., palletizing items, de-palletizing items, singulating items, and/or kitting items, etc.). For example, the state estimation module/model is developed by iteratively performing a plurality computer simulations and determining the state estimation module/model based on an evaluation of the resulting state estimations (e.g., determining a best model or set of best models such as based on a cost function). In some embodiments, the system performs the plurality of computer simulations in parallel (e.g., a server spins up a cluster(s) of virtual machines that are respectively configured to perform a simulation). Using computer simulations to run a plurality of simulations improves the efficiency with which the state estimation module/model is developed by saving the time (e.g., the system saves time otherwise required to control a robot to pick and place items and/or human intervention during such physical simulations, etc.).

Various embodiments for determining a state estimation module/model using computer simulations is also more extensible than related art system. For example, because related art systems require extensive time to physically simulate different methods/techniques for picking and placing items (e.g., palletizing items, de-palletizing items, etc.), related art systems generally develop the state estimation module/model using conventional items (e.g., items having conventional attributes such as weight, shape, rigidity, deformability, etc.). In other words, related art systems are not configured to take into account bespoke items. A bespoke item may correspond to an item having unconventional attributes or an unconventional combination of attributes (e.g., an unconventional set of conventional attributes, etc.). Examples of bespoke items include items that are not rectangular-shaped, items having rounded or crushed box edges/corners, etc. Conversely, according to various embodiments, the system to determine the state estimation module/model using a computer simulation(s) enables simulations to be performed in which movement (e.g., placement on a stack of items) of bespoke items are simulated.

Various embodiments for determining a state estimation module/model are more reflective of noise that manifests in sensor data or a difference between the sensor data and the geometric model. For example, the sensor data may comprise noise that is not reflective of the physical state. Examples of sources of noise in sensor data include: (i) reflection of light from items (e.g., a surface of an item) or objects within the workspace, (ii) distortion of images such as at the edge of a field of view of a camera, (iii) voids in images such as based on a field of view of the vision system being obstructed, etc. Related art systems do not consider noise generated by the vision system or by a robotic arm in connection with determining a state estimation module/model or to determine an estimated system.

Noise in data used to determine estimated states can arise from various sources within the system. Examples of sources for noise in the system include noise generated by operation of a robotic arm to move items, and noise comprised in the vision system (e.g., based on a noisy signal or otherwise an imprecision of a camera, etc.). For example, noise may arise in operation of a robotic arm to place items. Actual operation of the robotic arm to place an item may differ from an idealized operation of the actual operation (e.g., an operation that the geometric model assumes was performed). Accordingly, a physical state of the workspace may diverge from the estimated state. As another example, noise may arise in data captured/provided by cameras in the workspace (e.g., by the vision system).

Noise generated by a vision system (e.g., by a sensor) is difficult to categorize. For example, most noise comprised in sensor data is non-linear. Noise generated by vision systems is generally deemed to be Gaussian models in state estimation models. However, most noise comprised in sensor data is not Gaussian. Accordingly, current state estimation models are generally inaccurate. According to various embodiments, the noise comprised in the sensor data is more accurately modeled. For example, various embodiments implement a machine learning process to determine a state estimation model (e.g., a model for determining an estimated state, such as determining an estimated state using a geometric noise in which noise is simulated). As another example, the implementing the machine learning process to determine the state estimation model may include implementing the machine learning process to model a noise profile in the system (e.g., noise generated by operation of the robotic arm to move an items, such as a sway in an item during movement; noise generated by the vision system when capturing the sensor data, etc.). Examples of machine learning processes that can be implemented in connection with training the model include random forest, linear regression, support vector machine, naive Bayes, logistic regression, K-nearest neighbors, decision trees, gradient boosted decision trees, K-means clustering, hierarchical clustering, density-based spatial clustering of applications with noise (DBSCAN) clustering, principal component analysis, etc.

Various embodiments include a system, method, and/or device that develops, determines, and/or updates a state estimation module/model based at least in part on implementing a computer simulation of a palletization/depalletization of a simulated set of items using the state estimation module/model. The simulated set of items may be a virtual set of items, including a virtual representation of an item, such as using geometric data and/or other attributes associated with an item being stored at the system (e.g., height, weight, size, center of gravity, type of packaging, rigidity, etc.). In some embodiments, the physical world is simulated based at least in part on the introduction of noise in connection with computer simulation of a palletization/depalletization of a simulated set of items using the state estimation module/model.

According to various embodiments, the system models noise (e.g., noise comprised in sensor data, or noise corresponding to differences between a geometric model and the sensor data). The modelling of noise in connection with determining an estimated state can provide a better final estimate of the state of the system (e.g., a more accurate/precise estimated state). In some embodiments, the system estimates a type/extent of noise (e.g., point cloud noise) corresponding to a destination location at which a particular item is geometrically placed (e.g., where the system assumes the object is placed/to be placed in an idealized state).

An example of a type/extent of noise estimated by the system comprises the context in which the particular item is placed at location corresponding to an edge of a field of view of a camera, or the vision system generally, the system estimates the type of noise as being noise characteristic of an edge of a camera's field of view, etc. (e.g., a noise profile corresponding to an edge of the vision system). If items (e.g., images captured) are at an edge of a field of view of a camera, the items may appear more noisy than items (e.g., images captured) at a center of a field of view of the camera. For example, images obtained by the camera may comprise distortions at the edges of the field of view.

An example of a type/extent of noise estimated by the system comprises the context in which the particular item is placed in proximity to another items, such as within a predefined distance of another item or next to the other item such that the two items are in contact. In such a context, sensor data may comprise noise at the boundaries of items. For example, the edges of the respective items may not be precisely identified or the boundaries of the items may merge (e.g., the items may appear as a single item).

In some embodiments, the system determines an estimated state of a workspace. The system uses the estimated state to determine a plan for moving an item such as placing the item among a stack of items. In response to determining the plan for moving the item, the system can update a geometric model to reflect the movement (e.g., placement) of the item. The updated geometric model can be used in connection with determining an updated estimated state. For example, the updated estimated state may correspond to the updated geometric model, or the updated estimated state may correspond to a combination of the updated geometric model and sensor data captured by a vision system. In some embodiments, the system models noise that is expected to be manifested in sensor data or a difference between sensor data and the geometric model (e.g., an inaccurate placement based on a miscalibration of the robotic arm, or inaccurate placement caused by a swaying of the item during the moving, etc.). For example, the system models the noise based on a type/extent of noise that the system expects to be manifested (e.g., based on a destination location of the item placed, an edge of a camera field of view, etc.). In response to modelling the noise (e.g., determining a noise profile), the system can modify (e.g., adjust) the updated estimated state (e.g., the updated geometric model) based at least in part on the expected noise.

In some embodiments, the system may model an adjustment that compensates for the noise. The system may determine the adjustment to be implemented with respect to the estimated state (e.g., the geometric model and/or sensor data) based at least in part on an expected noise (e.g., an expected type of noise and/or an expected extent of such noise, etc.).

As an example, if the destination location of the item is at an edge of a camera field of view, the system may determine that the expected noise corresponds to a noise profile associated with distortions that occur at edges of a field of view. In response to determining the expected noise, the system may adjust the sensor data (e.g., to cancel out the expected noise) before determining the estimated state based at least in part on the geometric and the sensor data. For example, the system cancels out the expected noise from the sensor data before the geometric model and sensor data are combined to determine an estimated state.

As another example, an item may sway during movement of the item by a robotic arm from a source location to a destination location. In the idealized state (e.g., the geometric model), the item is moved precisely according to the plan and the environmental considerations such as sway are not considered. However, if the item sways then the item may be off center (e.g., the location of the item may deviate from the idealized state) during placement of the item by the robotic arm. As an example, the system may determine that the item is expected to experience sway, such as based on an attribute associated with the item (e.g., a weight, a shape, a type of packaging, etc.). As another example, the system may determine that the item is experienced sway based on information obtained by force sensors during movement of the item to the destination location. In response to determining that placement of the item is expected to be impacted by sway generated during movement of the item, the system may update the geometric model (e.g., the estimated state) based on the destination location and the expected noise. For example, the system modifies the geometric model may update the idealized location of the item in the model to account for noise generated based on the sway, etc. The system can estimate a location of the item based on the noise profile associated with the sway.

According to various embodiments, the system determines the estimated state at least in part by performing an interpolation based on at least part of the geometric model and at least part of the sensor data. In some embodiments, an interpolation process performed with respect to a first part of the geometric model and a first part of the sensor data to obtain a first part of the estimated state is different from an interpolation performed with respect to a second part of the geometric model and a second part of the sensor data to obtain a second part of the estimated state.

In some embodiments, the system uses the estimated state in connection with determining a plan to palletize one or more items. For example, the system uses the estimated state (e.g., an estimated state adjusted to reflect a noise profile(s)) in connection with selecting an item from a conveyor (or other item source) comprising a set of items (e.g., a sequence of items input to the workspace), controlling a robotic arm to pick the item, select a destination location corresponding to a position on a pallet or among a stack of items on a pallet, move the item, and place the item at the destination location.

In some embodiments, the system uses the estimated state in connection with determining a plan to depalletize one or more items. For example, the system uses the estimated state in connection with selecting an item from a pallet or from among a stack of items on a pallet, controlling a robotic arm to pick the item, select a destination location corresponding to a position on a receptacle or conveyor (e.g., that carries the item from the workspace), move the item, and place the item at the destination location.

In some embodiments, the system uses the estimated state in connection with determining a plan to singulate one or more items. For example, the system uses the estimated state in connection with selecting an item from a chute comprising a set of items, controlling a robotic arm to pick the item, select a destination location (e.g., a tray, a segment of a conveyor, etc.), move the item, and place the item at the destination location.

In some embodiments, the system uses the estimated state in connection with determining a plan to perform a kitting with respect to one or more items. For example, the system uses the estimated state in connection with selecting an item from kitting shelf system comprising a plurality of shelves on which items are disposed, controlling a robotic arm to pick the item from a shelf, select a destination location (e.g., a receptacle such as a box, a tote, etc.), move the item, and place the item at the destination location.

According to various embodiments, the geometric model is determined based at least in part on one or more attributes for one or more items in the workspace. For example, the geometric model reflects respective attributes of a set of items (e.g., one or more of a first set that are palletized/stacked, and a second set of items that is to be palletized/stacked, etc.). Examples of an item include an item size (e.g., dimensions of the item), a center of gravity, a rigidity of the item, a type of packaging, a location of an identifier, a deformability of the item, a shape of the item, etc. Various other attributes of an item or object within the workspace may be implemented. As another example, the geometric model comprises an expected stability of one or more items stacked on or in the receptacle (e.g., a pallet). The geometric model may include an expected stability of a set of items (e.g., the stack of items) and/or an expected stability of individual items comprised in the stack of items. In some embodiments, the system determines an expected stability of an item based at least in part on (i) one or more attributes of the item; and (ii) one or more expected interactions with respect to the item and another item or object (e.g., a pallet) in the workspace. For example, the system may determine the expected stability based on a determination of an attribute of another item or object contact the item for which the expected stability is being computed. Examples of attributes of other items that may impact the expected stability of a particular item include rigidity, deformability, a size, a type of packaging, etc. As an example, if a particular item is rests on another item that is rigid, the particular item is likely to have an relatively high expected stability as compared to a case where the particular item rests on another item that is not rigid or less rigid. As another example, if a particular item is rests on another item that is deformable, such as comprised a soft packaging, the particular item is likely to have a lesser expected stability as compared to a case where the particular item rests on another item that is not deformable or less deformable. As another example, if a particular item rests on another item having a top surface area is greater than a bottom surface areas of the particular item, or if a relatively high percentage of a bottom surface of the particular item is supported by a top surface of another item, then the expected stability of the item is relatively high or at least higher than if the particular item has a top surface area smaller than a bottom surface area of the particular item, or if a relatively high percentage of the bottom surface of the particular item is not supported/interacting with a top surface of another item.

In some embodiments, the system adjusts the sensor data to account for noise (e.g., sensor noise). The system can estimate the noise comprised in the sensor data based at least in part on an empirical analysis of the vision system. For example, an empirical analysis of the performance of the vision system can be performed to determine noise captured in (e.g., inherent in) the sensor data. In some embodiments, the system stores a predetermined sensor noise profile associated with the vision system. The system can use the sensor noise profile in connection with adjusting the sensor data to account for the noise. For example, the system can apply an adjustment to cancel out the expected noise based at least in part on the sensor profile. The empirical analysis of the performance of the vision system can include (i) manually/physically measuring an item or a workspace, (ii) capturing the same using the vision system, and (iii) determining a difference between the manual/physical measurement of the item/workspace and the measurements of the same using the sensor data (e.g., using digital processing, etc.). The system may deem the noise profile to be the difference between the manual/physical measurement of the item/workspace and the measurements of the same using the sensor data. As an example, the system determines a variance in the sensor data and determines the sensor noise profile based at least in part on the variance. The empirical analysis can be performed with respect to a statistically significant set of experiments/measurements. Examples of noise (or inaccuracies in the sensor data) may include (i) imprecision of an image at edges of the field of view of the vision system, (ii) glare/reflection from items or other objects in the workspace, etc.

In some embodiments, the system adjusts the geometric model to account for noise (e.g., geometric noise or imprecision arising from translation of the geometric model to the physical world such as via controlling a robotic arm). The system can estimate the noise comprised in the geometric model based at least in part on an empirical analysis of the precision of the robotic control or other objects within the workspace (e.g., estimated deformation of a pallet, deviations in placement of pallet versus a location used in the geometric model, etc.). For example, an empirical analysis of the performance of the control of the robotic arm (e.g., to perform a task such as placing an item) can be performed to determine noise captured in (e.g., inherent in) the geometric model. As an example, the system determines a variance in the geometric model and determines the geometric noise profile based at least in part on the variance. In some embodiments, the system stores a predetermined geometric noise profile associated with the vision system. The system can use the geometric noise profile in connection with adjusting the geometric model to account for the noise. For example, the system can apply an adjustment to cancel out the expected noise comprised in the geometric model (e.g., noise generated based on controlling a robot according to a plan determined based on the geometric model).

According to various embodiments, the system uses the geometric model and the sensor data to determine a best estimate of a state of the workspace. The system can adjust for (e.g., cancel) noise in one or more of geometric model and/or sensor data. In some embodiments, the system detects anomalies or differences between a state according to the geometric model and a state according to the sensor data. In response to determining an anomaly or difference between the geometric model and the sensor data, the system can make a best estimate of the state notwithstanding the anomaly or difference. For example, the system determines whether to use the geometric model or the sensor data, or a combination of (e.g., an interpolation between) the geometric model and the sensor data, etc. In some embodiments, the system determines the estimated state on a segment-by-segment basis (e.g., a voxel-by-voxel basis in the workspace, an item-by-item basis, or object-by-object basis, etc.). For example, a first part of the workspace may be estimated using only the geometric model, a second part of the workspace may be estimated using only the sensor data (e.g., in the event of an anomaly in the geometric model), and/or a third part of the workspace may be estimated based on a combination of the geometric model and the sensor data.

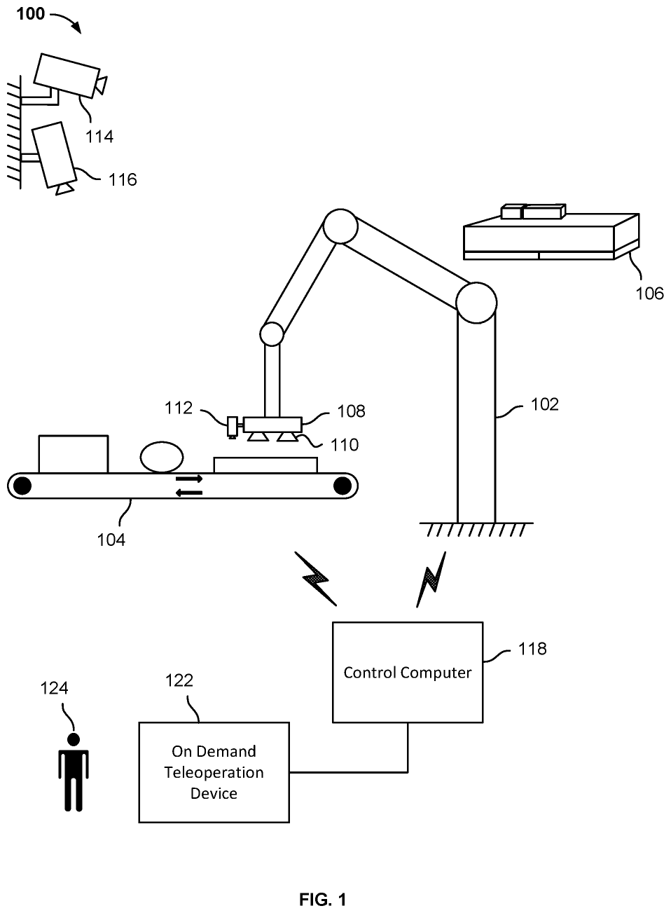

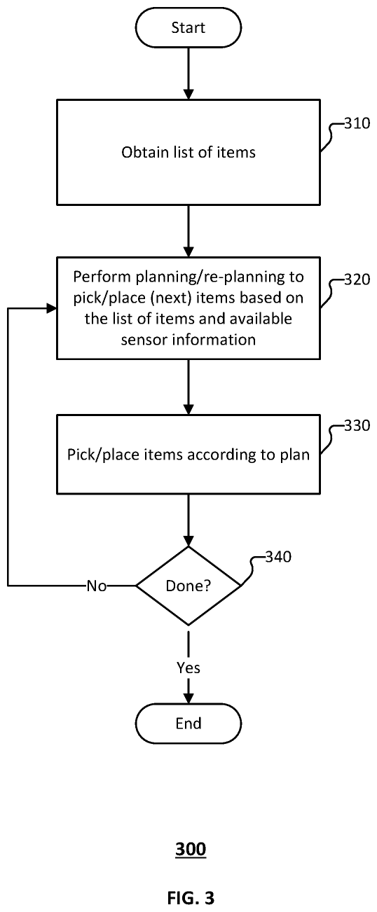

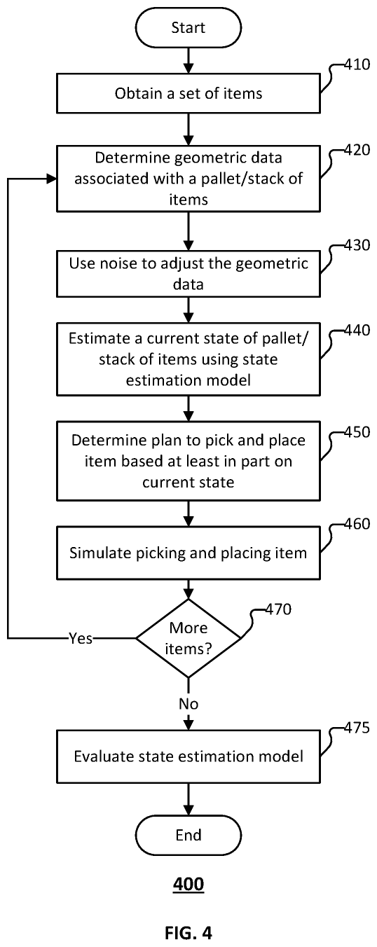

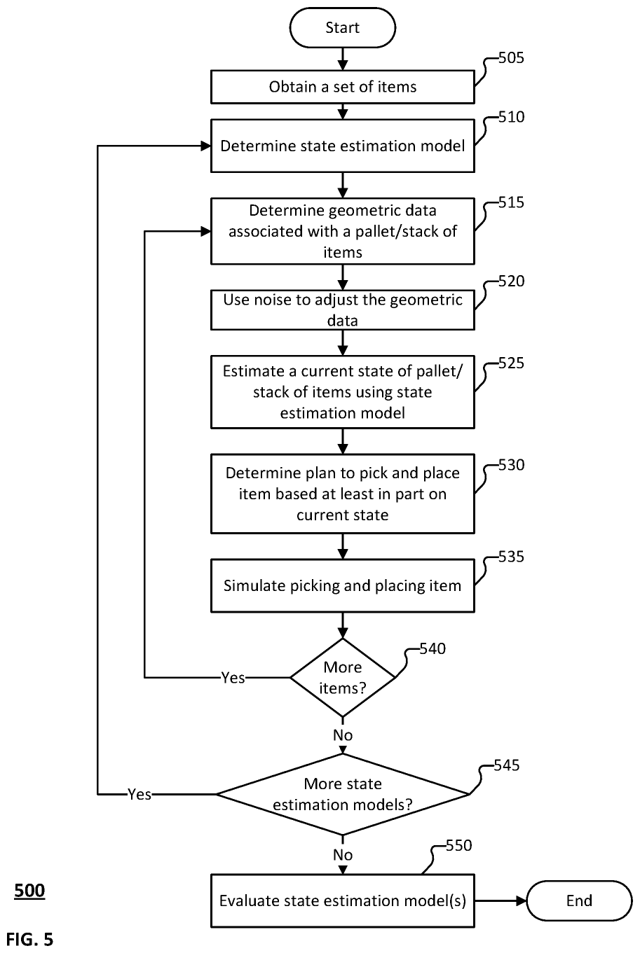

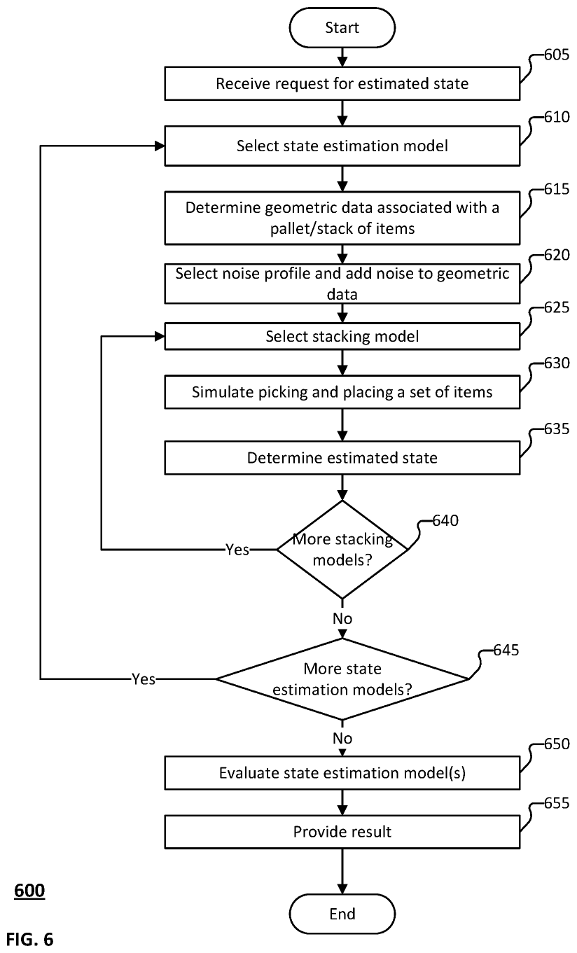

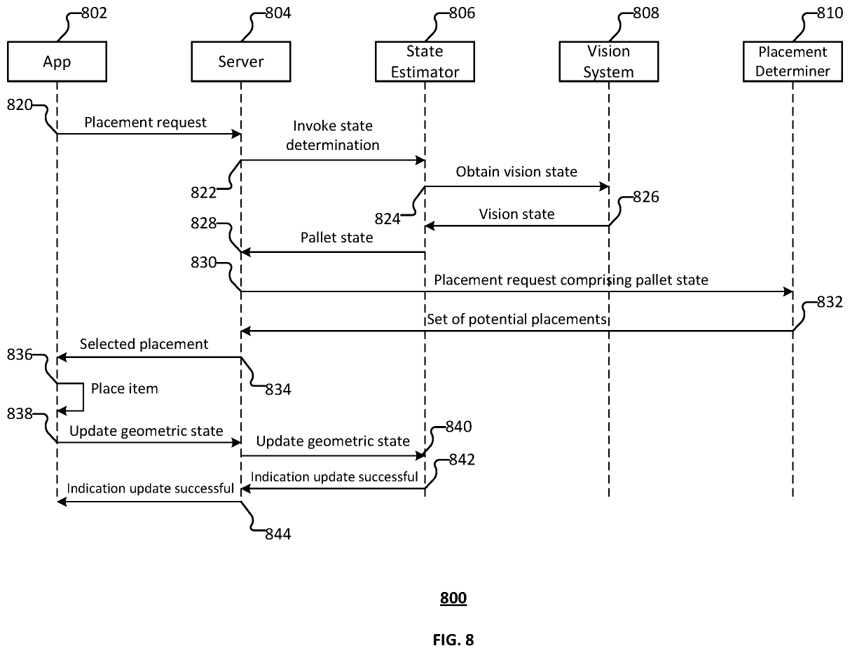

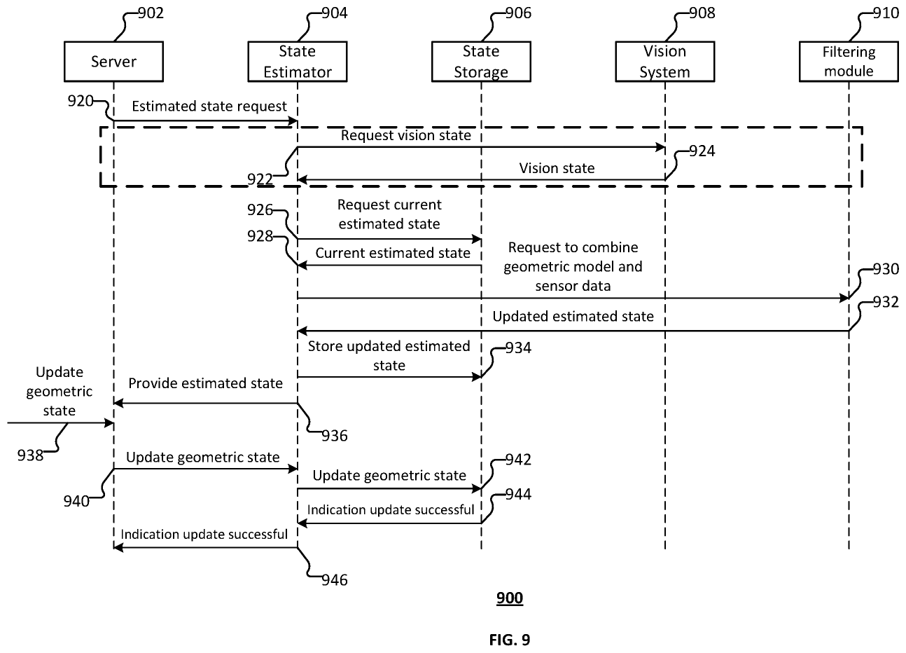

FIG. 1 is a diagram illustrating a robotic system to palletize and/or depalletize heterogeneous items according to various embodiments. In some embodiments, robotic system 100 implements at least part of process 300 of FIG. 3, process 400 of FIG. 4, process 500 of FIG. 5, process 600 of FIG. 6, process 800 of FIG. 8, process 900 of FIG. 9, process 1000 and/or process 1100.

In the example shown, robotic system 100 includes a robotic arm 102. In this example the robotic arm 102 is stationary, but in various alternative embodiments, robotic arm 102 may be fully or partly mobile, e.g., mounted on a rail, fully mobile on a motorized chassis, etc. As shown, robotic arm 102 is used to pick arbitrary and/or dissimilar items (e.g., boxes, packages, etc.) from a conveyor (or other source) 104 and stack them on a pallet (e.g., platform or other receptacle) 106. The pallet (e.g., platform or other receptacle) 106 may comprise a pallet, a receptacle, or base with wheels at the four corners and at least partially closed on three of four sides, sometimes referred to as a three-sided “roll pallet”, “roll cage”, and/or “roll” or “cage” “trolley”. In other embodiments, a roll or non-wheeled pallet with more, fewer, and/or no sides may be used. In some embodiments, other robots not shown in FIG. 1 may be used to push receptacle 106 into position to be loaded/unloaded and/or into a truck or other destination to be transported, etc.

In some embodiments, a plurality of receptacles 106 may be disposed around robotic arm 102 (e.g., within a threshold proximity or otherwise within range of the robotic arm). The robotic arm 102 may simultaneously (e.g., concurrently and/or contemporaneously) stack one or more items on the plurality of pallets. Each of the plurality of pallets may be associated with a manifest and/or order. For example, each of the pallets may be associated with a preset destination (e.g., customer, address, etc.). In some instances, a subset of the plurality of pallets may be associated with a same manifest and/or order. However, each of the plurality of pallets may be associated with different manifests and/or orders. Robotic arm 102 may place a plurality of items respectively corresponding to a same order on a plurality of pallets. Robotic system 100 may determine an arrangement (e.g., a stacking of items) on the plurality of pallets (e.g., how the plurality of items for an order are to be divided among the plurality of pallets, how the items on any one pallet are to be stacked, etc.). Robotic system 100 may store one or more items (e.g., item(s) for an order) in a buffer or staging area while one or more other items are stacked on a pallet. As an example, the one or more items may be stored in the buffer or staging area until such time that robotic system 100 determines that the respective placement of the one or more items on the pallet (e.g., on the stack) satisfies (e.g., exceeds) a threshold fit or threshold stability. The threshold fit or threshold stability may be a predefined value or a value that is empirically determined based at least in part on historical information. A machine learning algorithm may be implemented in connection with determining whether placement of an item on a stack is expected to satisfy (e.g., exceeds) a threshold fit or threshold stability, and/or in connection with determining the threshold fit or threshold stability (e.g., the thresholds against which a simulation or model is measured to assess whether to place the item on the stack).

In the example shown, robotic arm 102 is equipped with a suction-type end effector (e.g., end effector 108). End effector 108 has a plurality of suction cups 110. Robotic arm 102 is used to position the suction cups 110 of end effector 108 over an item to be picked up, as shown, and a vacuum source provides suction to grasp the item, lift the item from conveyor 104, and place the item at a destination location on receptacle 106. Various types of end effectors may be implemented.

In various embodiments, robotic system 100 comprises a vision system that is used to generate a model of the workspace (e.g., a 3D model of the workspace and/or a geometric model). For example, one or more of 3D or other camera(s) 112 mounted on end effector 108 and cameras 114, 116 mounted in a space in which robotic system 100 is deployed are used to generate image data used to identify items on conveyor 104 and/or to determine a plan to grasp, pick/place, and stack the items on receptacle 106 (or place the item in the buffer or staging area, as applicable). In various embodiments, additional sensors not shown may be used to identify (e.g., determine) attributes of an item, grasp the item, pick up the item, move the item through a determined trajectory, and/or place the item in a destination location on or in receptacle 106 items on conveyor 104 and/or other sources and/or staging areas in which items may be located and/or relocated, e.g., by system 100. Examples of such additional sensors not shown may include weight or force sensors embodied in and/or adjacent to conveyor 104 and/or robotic arm 102, force sensors in the x-y plane and/or z-direction (vertical direction) of suction cups 110.

In the example shown, cameras 112 are mounted on the side of the body of end effector 108, but in some embodiments, cameras 112 and/or additional cameras may be mounted in other locations, such as on the underside of the body of end effector 108, e.g., pointed downward from a position between suction cups 110, or on segments or other structures of robotic arm 102, or other locations. In various embodiments, cameras such as 112, 114, and 116 may be used to read text, logos, photos, drawings, images, markings, barcodes, QR codes, or other encoded and/or graphical information or content visible on and/or comprising items on conveyor 104.

In some embodiments, robotic system 100 comprises a dispenser device (not shown) that is configured to dispense a quantity of spacer material from a supply of spacer material in response to the control signal. The dispenser device may be disposed on robotic arm 102, or within proximity of the workspace (e.g., within a threshold distance of the workspace). For example, the dispenser device may be disclosed within the workspace of robotic arm 102 such that the dispenser device dispenses spacer material on or around receptacle 106 (e.g., pallet), or within a predetermined distance of end effector 108 of robotic arm 102. In some embodiments, the dispenser device comprises a mounting hardware configured to mount the dispenser device on or adjacent to an end effector 108 of robotic arm 102. The mounting hardware is at least one of a bracket, a strap, and one or more fasteners, etc. As an example, the dispenser device may comprise a biasing device/mechanism that biases supply material within the dispenser device to be ejected dispensed from dispenser device. The dispenser device may include a gating structure that is used to control the dispensing of spacer material (e.g., to prevent spacer material to be dispensed without actuation of the gating structure, and to permit dispensing of the spacer material to be dispensed in response to actuation).

The dispenser device may comprise a communication interface configured to receive a control signal. For example, the dispenser device may be in communication with one or more terminals such as control computer 118. The dispenser device may communicate with the one or more terminals via one or more wired connections and/or one or more wireless connections. In some embodiments, the dispenser device communicates information to the one or more terminals. For example, the dispenser device may send to control computer 118 an indication of a status of the dispenser device (e.g., an indication of whether the dispenser device is operating normally), an indication of a type of spacer material comprised in dispenser device, an indication of a supply level of the spacer material in the dispenser device (e.g., an indication of whether the dispenser device is full, empty, half full, etc.), etc. Control computer 118 may be used in connection with controlling the dispenser device to dispense a quantity of spacer material. For example, control computer 118 may determine that a spacer is to be used in connection with palletizing one or more items, such as to improve an expected stability of the stack of items on/in receptacle 106. Control computer 118 may determine the quantity of spacer material (e.g., a number of spacers, an amount of spacer material, etc.) to use in connection with palletizing the one or more items. For example, the quantity of spacer material to use in connection with palletizing the one or more items may be determined based at least in part on determining a plan for palletizing the one or more items.

In some embodiments, the dispenser device comprises an actuator configured to dispense a quantity of spacer material from a supply of spacer material in response to the control signal. In response to determining that a spacer/spacer material is to be used in connection with palletizing one or more items, control computer 118 may generate the control signal to cause the actuator to dispense the quantity of spacer material. The control signal may comprise an indication of the quantity of spacer material to be used as the spacer.

According to various embodiments, a spacer or a spacer material is rigid block. For example, a spacer or a spacer material may be a rigid block of foam. In some embodiments, a spacer or a spacer material comprises polyurethane.

In some embodiments, the supply of spacer material comprises a plurality of precut blocks. The plurality of precut blocks may be preloaded into a spring-loaded cartridge that biases the plurality of precut blocks to a dispensing end. In response to a precut block being dispensed from the cartridge, another of the plurality of precut blocks is pushed to a next-in-line position to be dispensed from the cartridge.

In some embodiments, the supply of spacer material comprises one or more of a larger block of spacer material, a strip of spacer material, and a roll of spacer material. The dispenser device or a robotic system 100 may comprises a cutter that is configured to cut the quantity of spacer material from the supply of the spacer material. In response to the control signal being provided to the actuator, the actuator may cause the cutter to cut the quantity of the spacer material from the supply of the spacer material.

In some embodiments, the supply of the spacer material comprises a liquid precursor. In response to the control signal being provided to the actuator, the actuator causes the quantity of the spacer material to be dispensed onto a surface of a pallet or a stack of items on the pallet. The dispensed precursor may harden after being dispensed onto the surface of the pallet or the stack of items on the pallet.

In some embodiments the supply of spacer material comprises an extruded material. In response to the control signal being provided to the actuator, the extruded material is filled to one or more of a desired size and a desired firmness. The extruded material may be sealed in response to a determination that the extruded material is filled to the one or more of the desired size and the desired firmness. In some embodiments, the extruded material is filled with a fluid. The fluid may be one or more of air, water, etc. In some embodiments, the extruded material is filled with a gel.

In various embodiments, a robotically controlled dispenser tooling or machine fills the void between and/or adjacent to boxes to prepare the surface area for the next box/layer being placed. In some embodiments, robotic system 100 may use a robotic arm 102 to pick/place predefined cut material and/or may dynamically trim the spacer material to fit the need of the surface area of the next item being placed. In some embodiments, the robotically controlled the dispenser device, or the robotic palletization system comprising the robotically controlled dispenser device, comprises a device to trim the size of a rectangular solid from a long tube and/or packaging, and place the rectangular solid on an existing pallet in connection with preparing the surface area for a next box or item which the system determines may not normally fit on the pallet surface area (e.g., on an upper surface of a previous layer). The spacer may include, without limitation, foam, an inflated air plastic packet, wood, metal, plastic, etc. The dispenser device may place (e.g., eject, dispense, etc.) the rectangular solid (e.g., the spacer) on the pallet directly, and/or the device may dispense the rectangular solid (e.g., the spacer) in proximity of the robotic arm, and the end effector may reposition/place the rectangular solid (e.g., the spacer) on the pallet surface area. The dispenser device may dispense a predetermined amount (e.g., a correct amount or an expected amount) of the spacer material to correct or improve the surface area discrepancy between boxes or items on the layer (e.g., on the upper surface of the layer) to prepare the surface area for a next box or item.

Referring further to FIG. 1, in the example shown robotic system 100 includes a control computer 118 configured to communicate, in this example, via wireless communication (but in one or both of wired and wireless communication in various embodiments) with elements such as robotic arm 102, conveyor 104, end effector 108, and sensors, such as cameras 112, 114, and 116 and/or weight, force, and/or other sensors not shown in FIG. 1. In various embodiments, control computer 118 is configured to use input from sensors, such as cameras 112, 114, and 116 and/or weight, force, and/or other sensors not shown in FIG. 1, to view, identify, and determine one or more attributes of items to be loaded into and/or unloaded from receptacle 106. In various embodiments, control computer 118 uses item model data in a library stored on and/or accessible to control computer 118 to identify an item and/or its attributes, e.g., based on image and/or other sensor data. Control computer 118 uses a model corresponding to an item to determine and implement a plan to stack the item, along with other items, in/on a destination, such as receptacle 106. In various embodiments, the item attributes and/or model is used to determine a strategy to grasp, move, and place an item in a destination location, e.g., a determined location at which the item is determined to be placed as part of a planning/replanning process to stack items in/on the receptacle 106.

In the example shown, control computer 118 is connected to an “on demand” teleoperation device 122. In some embodiments, if control computer 118 cannot proceed in a fully automated mode, for example, a strategy to grasp, move, and place an item cannot be determined and/or fails in a manner such that control computer 118 does not have a strategy to complete picking and placing the item in a fully automated mode, then control computer 118 prompts a human user 124 to intervene, e.g., by using teleoperation device 122 to operate the robotic arm 102 and/or end effector 108 to grasp, move, and place the item.

A user interface pertaining to operation of robotic system 100 may be provided by control computer 118 and/or teleoperation device 122. The user interface may provide a current status of robotic system 100, including information pertaining to a current state of the pallet (or stack of items associated therewith), a current order or manifest being palletized or de-palletized, a performance of robotic system 100 (e.g., a number of items palletized/de-palletized by time), etc. A user may select one or more elements on the user interface, or otherwise provide an input to the user interface, to activate or pause robotic system 100 and/or a particular robotic arm in robotic system 100.

According to various embodiments, robotic system 100 implements a machine learning process to model a state of a pallet such as to generate a model of a stack on the pallet. The machine learning process may include an adaptive and/or dynamic process for modeling the state of the pallet. The machine learning process may define and/or update/refine a process by which robotic system 100 generates a model of the state of the pallet. The model may be generated based at least in part on input from (e.g., information obtained from) one or more sensors in robotic system 100 such as one or more sensors or sensor arrays within the workspace of robotic arm 102. The model may be generated based at least in part on a geometry of the stack, a vision response (e.g., information obtained by one or more sensors in the workspace), and the machine learning processes, etc. Robotic system 100 may use the model in connection with determining an efficient (e.g., maximizing/optimizing an efficiency) manner for palletizing/de-palletizing one or more items, and the manner for palletizing/de-palletizing may be bounded by a minimum threshold stability value. The process for palletizing/de-palletizing the one or more items may be configurable by a user administrator. For example, one or more metrics by which the process for palletizing/de-palletizing is maximized may be configurable (e.g., set by the user/administrator).

In the context of palletizing one or more items, robotic system 100 may generate the model of the state of the pallet in connection with determining whether to place an item on the pallet (e.g., on the stack), and selecting a plan for placing the item on the pallet, including a destination location at which the item is to be placed and a trajectory along which the item is to be moved from a source location (e.g., a current destination such as a conveyor) to the destination location. Robotic system 100 may also use the model in connection with determining a strategy for releasing the item, or otherwise placing the item on the pallet (e.g., applying a force to the item to fit the item on the stack). The modelling of the state of the pallet may include simulating placement of the item at different destination locations on the pallet (e.g., on the stack) and determining corresponding different expected fits and/or expected stability (e.g., a stability metric) that is expected to result from placement of the item at the different locations. Robotic system 100 may select a destination location for which the expected fit and/or expected stability satisfies (e.g., exceeds) a corresponding threshold value. Additionally, or alternatively, robotic system 100 may select a destination location that optimizes the expected fit (e.g., of the item on the stack) and/or expected stability (e.g., of the stack).

Conversely, in the context of de-palletizing one or more items from a pallet (e.g., a stack on the pallet), robotic system 100 (e.g., control computer 118) may generate the model of the state of the pallet in connection with determining whether to remove an item on the pallet (e.g., on the stack), and selecting a plan for removing the item from the pallet. The model of the state of the pallet may be used in connection with determining an order in which items are removed from the pallet. For example, control computer 118 may use the model to determine whether removal of an item is expected to cause stability of the state of the pallet (e.g., the stack) to drop below a threshold stability. Robotic system 100 (e.g., control computer 118) may simulate removal of one or more items from the pallet and select an order for removing items from the pallet that optimizes the stability of the state of the pallet (e.g., the stack). Robotic system 100 may use the model to determine a next item to remove from the pallet. For example, control computer 118 may select an item as a next item to remove from the pallet based at least in part on a determination that an expected stability of the stack during and/or after removal of the item exceeds a threshold stability. The model and/or the machine learning process may be used in connection with determining strategies for picking an item from the stack. For example, after an item is selected to be the next item to remove from the stack, robotic system 100 may determine the strategy for picking the item. The strategy for picking the item may be based at least in part on the state of the pallet (e.g., a determined stability of the stack), an attribute of the item (e.g., a size, shape, weight or expected weight, center of gravity, type of packaging, etc.), a location of the item (e.g., relative to one or more other items in the stack), an attribute of another item on the stack (e.g., an attribute of an adjacent item, etc.), etc.

According to various embodiments, a machine learning process is implemented in connection with improving grasping strategies (e.g., strategies for grasping an item). Robotic system 100 may obtain attribute information pertaining to one or more items to be palletized/de-palletized. The attribute information may comprise one or more of an orientation of the item, a material (e.g., a packaging type), a size, a weight (or expected weight), or a center of gravity, etc. Robotic system 100 may also obtain a source location (e.g., information pertaining to the input conveyor from which the item is to be picked), and may obtain information pertaining to a pallet on which the item is to be placed (or set of pallets from which the destination pallet is to be determined such as a set of pallets corresponding to the order for which the item is being stacked). In connection with determining a plan for picking and placing the item, robotic system 100 may use the information pertaining to the item (e.g., the attribute information, destination location, etc.) to determine a strategy for picking the item. The picking strategy may include an indication of a picking location (e.g., a location on the item at which the robotic arm 102 is to engage the item such as via the end effector). The picking strategy may include a force to be applied to pick the item and/or a holding force by which the robotic arm 102 is to grasp the item while moving the item from a source location to the destination location. Robotic system 100 may use machine learning processes to improve the picking strategies based at least in part on an association between information pertaining to the item (e.g., the attribute information, destination location, etc.) and performance of picking the item (e.g., historical information associated with past iterations of picking and placing the item or similar items such as items sharing one or more similar attributes).

According to various embodiments, robotic system 100 may determine to use a spacer or a quantity of the spacer material in connection with palletizing one or more items in response to a determination that the use of the spacer or quantity of the spacer material will improve the result of a stack of items on the pallet (e.g., improve the stability of the stack of items). In some embodiments, the determination that the placing of the one or more spacers in connection with placing the set of N items on the pallet will result in an improved stack of items on the pallet is based at least in part on one or more of a packing density, a level top surface, and a stability. In some embodiments, the determination that the placing of the one or more spacers in connection with placing the set of N items on the pallet will result in an improved stack of items on the pallet is based at least in part on a determination that a packing density of the stack of items with the set of N items is higher than a packing density if the set of N items are placed on the pallet without the one or more spacers. In some embodiments, the determination that the placing of the one or more spacers in connection with placing the set of N items on the pallet will result in an improved stack of items on the pallet is based at least in part on a determination that a top surface is more level than a top surface if the set of N items are placed on the pallet without the one or more spacers. In some embodiments, the determination that the placing of the one or more spacers in connection with placing the set of N items on the pallet will result in an improved stack of items on the pallet is based at least in part on a determination that a stability of the stack of items with the set of N items is higher than a stability if the set of N items is placed on the pallet without the one or more spacers. N may be a positive integer (e.g., a positive integer less than a total number of items that are to be palletized in the complete pallet).

As an example, because N may be less than a total number of items that are to be palletized, robotic system 100 may be limited in its optimization of the stack of items (e.g., robotic system 100 may only plan the placement of N items at a time). Accordingly, the use of one or more spacers increases the number of degrees of freedom associated with placing the N items. Robotic system 100 may use one or more spacers to optimize the stacking of the N items (or to achieve a “good enough” stack with the N items such as a stack that satisfies a minimum stability threshold). Robotic system 100 may use a cost function in connection with determining whether to use one or more spacers, a number of spacers to use, a placement of the spacers, etc. For example, the cost function may include one or more of a stability value, a time to place the one or more items, a packing density of the stack of items, a flatness value or degree of variability of the top of the upper surface of the stack of items, and a cost of supply material, etc.

According to various embodiments, control computer 118 controls robotic system 100 to place a spacer on a receptacle 106 (e.g., a pallet) or a stack of items in connection with improving a stability of the stack of items on the receptacle 106. As an example, the spacer may be placed in response to a determination that a stability of the stack of items is estimated (e.g., likely such as a probability that exceeds a predefined likelihood threshold value) to be improved if the spacer is used. As another example, control computer 118 may control robotic system 100 to use the spacer in response to a determination that a stability of the stack of items is less than a threshold stability value, and/or that the stability of the stack of items is estimated to be less than a threshold stability value in connection with the placement of a set of items (e.g., a set of N items, N being an integer).

According to various embodiments, control computer 118 may determine the stability of a stack of items based at least in part on a model of a stack of items and/or a simulation of placing a set of one or more items. A computer system may obtain (e.g., determine) a current model of a stack of items, and model (e.g., simulate) the placing of a set of item(s). In connection with modeling the stack of items, an expected stability of the stack of items may be determined. The modelling of the stack of items may include modelling the placement of a spacer in connection with the modelling of the placement of the set of item(s).

In some embodiments, control computer 118 may determine the stability of the stack of items (or simulated stack of items) based at least in part on one or more attributes of a top surface of the stack of items (or simulated stack of items) and/or spacers. For example, a measure of an extent to which the top surface is flat may be used in connection with determining the stability of the stack of items. The placing of a box on a flat surface may result in a stable placement and/or stack of items. As another example, a surface area of a flat region on the top surface may be used in connection with determining the stability or expected stability of the placement of an item on the stack of items. The larger a flat region on a top surface of the stack of items is relative to a bottom surface of an item being placed on the stack of items, the greater the likelihood that the stability of the stack of items will satisfy (e.g., exceed) a threshold stability value.

According to various embodiments, robotic system 100 generates a model of a pallet or a stack of one or more items on the pallet, and the spacer or spacer material is determined to be placed in connection with the palletization of one or more items based at least in part on the model of the pallet or the stack of one or more items on the pallet. Robotic system 100 may generate a model of at least a top surface of a pallet or a stack of one or more items on the pallet, determine a set of N items to be placed next on the pallet (e.g., N being a positive integer), determine that placing one or more spacers in connection with placing the set of N items on the pallet will result in an improved stack of items on the pallet compared to a resulting stack of placing the set of N items without spacers, generate one or more control signals to cause the actuator to dispense the quantity of spacer material corresponding to the one or more spacers, and provide the one or more control signals to the actuator in connection with placing the set of N items on the pallet.

According to various embodiments, variation in items (e.g., types of items) among items to be palletized may complicate the palletization of the items in a stable manner (e.g., a manner according to which the stability of the stack of items satisfies a threshold stability value). In some embodiments, control computer 118 may only be able to forecast a certain number of items that are to be palletized. For example, the system may have a queue/buffer of N items to be palletized, where N is a positive integer. N may be a subset of a total number of items to be stacked on a pallet. For example, N may be relatively small in relation to the total number of items to be stacked on the pallet. Accordingly, robotic system 100 may only be able to optimize the stacking of items using the next N known items. For example, robotic system 100 may determine a plan to stack one or more items according to the current state of the stack of items (e.g., a current model) and one or more attributes associated with the next N items to be stacked. In some embodiments, the use of one or more spacers may provide flexibility in the manner in which the next N items are to be stacked and/or may improve the stability of the stack of items.

Various embodiments include palletization of a relatively large number of mixed boxes or items on a pallet. The various boxes and items to be palletized may have different attributes such as heights, shapes, sizes, rigidity, packaging type, etc. The variations across one or more attributes of the various boxes or items may cause the placement of the items on a pallet in a stable manner to be difficult. In some embodiments, robotic system 100 (e.g., control computer 118) may determine a destination location (e.g., a location at which an item is to be placed) for an item having a greater surface area (e.g., a larger bottom surface) than the boxes or other items beneath the item being placed. In some embodiments, items having different heights (e.g., different box heights) may be placed on relatively higher areas of the pallet (e.g., a height greater than a height threshold value equal to a maximum pallet height multiplied by 0.5, a height greater than a height threshold value equal to a maximum pallet height multiplied by ⅔, a height greater than a height threshold value equal to a maximum pallet height multiplied by 0.75, a height greater than a height threshold value equal to a maximum pallet height multiplied by another predefined value).

According to various embodiments, a machine learning process is implemented in connection with improving spacer material dispensing/usage strategies (e.g., strategies for using spacer material in connection with palletizing one or more items). Robotic system 100 may obtain attribute information pertaining to one or more items to be palletized/de-palletized, and attribute information pertaining to one or more spacers to be used in connection with palletizing/de-palletizing the one or more items. The attribute information may comprise one or more of an orientation of the item, a material (e.g., a spacer material type), a size, a weight (or expected weight), a center of gravity, a rigidity, a dimension, etc. Robotic system 100 may also obtain a source location (e.g., information pertaining to the input conveyor from which the item is to be picked) and may obtain information pertaining to a pallet on which the item is to be placed (or set of pallets from which the destination pallet is to be determined such as a set of pallets corresponding to the order for which the item is being stacked). In connection with determining a plan for picking and placing the item, robotic system 100 may use the information pertaining to the item (e.g., the attribute information, destination location, etc.) to determine a strategy for palletizing the item (e.g., picking and/or placing the item). The palletizing strategy may include an indication of a picking location (e.g., a location on the item at which the robotic arm 102 is to engage the item such as via the end effector) and a destination location (e.g., a location on the pallet/receptacle 106 or stack of items). The palletizing strategy may include a force to be applied to pick the item and/or a holding force by which the robotic arm 102 is to grasp the item while moving the item from a source location to the destination location, a trajectory along which the robotic arm is to move the item to the destination location, an indication of a quantity, if any, of spacer material that is to be used in connection with placing the item at the destination location, and a plan for placing the spacer material. Robotic system 100 may use machine learning processes to improve the palletizing strategies based at least in part on an association between information pertaining to the item (e.g., the attribute information, destination location, etc.) and one or more of (i) performance of picking and/or placing the item (e.g., historical information associated with past iterations of picking and placing the item or similar items such as items sharing one or more similar attributes), (ii) performance of a stability of the stack of items after the item is placed at the destination location such as relative to an expected stability generated using a model of the stack of items (e.g., historical information associated with past iterations of palletizing the item or similar items such as items sharing one or more similar attributes), and (iii) performance of a stability of the stack of items after the item and/or spacer material is placed at the destination location such as relative to an expected stability generated using a model of the stack of items (e.g., historical information associated with past iterations of palletizing the item or similar items and/or spacers such as items/spacers sharing one or more similar attributes). In some embodiments, robotic system 100 may use machine learning processes to improve the use of one or more spacers in connection with palletizing strategies based at least in part on an association between information pertaining to the spacers and/or one or more items that are palletized (e.g., the attribute information, destination location, etc.), and a stability performance of palletizing a set of items using one or more spacers relative to an expected stability of the palletizing of the set of items using the one or more spacers (e.g., the expected stability based on a simulation of the palletizing of the items using a model of the stack of items).

The model generated by robotic system 100 can correspond to, or be based at least in part on, a geometric model. In some embodiments, robotic system 100 generates the geometric model based at least in part on one or more items that have been placed (e.g., items for which robotic system 100 controlled robotic arm 102 to place), one or more attributes respectively associated with at least a subset of the one or more items, one or more objects within the workspace (e.g., predetermined objects such as a pallet, a robotic arm(s), a shelf system, a chute, or other infrastructure comprised in the workspace). The geometric model can be determined based at least in part on running a physics engine on control computer 118 to model a stacking of items (e.g., models a state/stability of a stack of items, etc.). The geometric model can be determined based on an expected interaction of various components of the workspace, such as an item with another item, an object, or a simulated force applied to the stack (e.g., to model the use of a forklift or other device to raise/move a pallet or other receptacle on which a stack of items is located).

In some embodiments, robotic system 100 queries a state estimation module/module in connection with determining an estimated state for the workspace. The query for an estimated state may comprise a geometric model (e.g., a previous estimated state updated to reflect the movement of items since the estimated state was last determined) and sensor data captured by a vision system of robotic system 100 (e.g., by cameras 114 and 116). The state estimation module/module may be stored on control computer 118 or a remote system (e.g., a cloud service, etc.) with which control computer 118 communicates.

In some embodiments, the state estimation module/model is determined based at least in part on performing a computer simulation. The computer simulation comprises a simulation of movement (e.g., picking and placing) a set of one or more items and maintaining (e.g., determining and updating) a geometric model according to simulated movement of the set of one or more items. For example, the simulating the movement of the set of one or more items includes updating a geometric model to reflect movement of the movement of the set of one or more items in a manner that the computer expects the set of one or more items would have been placed.

According to various embodiments, the simulating the movement of the set of one or more items includes reflecting an expected noise profile for noise that the system expects to be generated during movement of the item (e.g., noise generated by operation of the robotic arm to move an items, such as a sway in an item during movement; noise generated by the vision system when capturing the sensor data, etc.). The expected noise can be programmatically generated (e.g., based on a noise profile(s)). In some embodiments, the noise profile(s) are modeled based on implementing a machine learning process with respect to a sample set of data (e.g., data that comprises states impacted by noise such as placement of items different from the idealized state, distortions in the sensor data captured by the vision system, etc.). Examples of sources of noise in sensor data include: (i) reflection of light from items (e.g., a surface of an item) or objects within the workspace, (ii) distortion of images such as at the edge of a field of view of a camera, (iii) voids in images such as based on a field of view of the vision system being obstructed, etc.

In some embodiments, the computer simulation is performed at least in part by combining geometric model data based on idealized simulated robotic placement of each item with programmatically generated noise data. The programmatically generated noise data reflects an estimation of the effect that one or more sources of noise in a real world physical workspace with which the computer simulation is associated would have on a real world state of one or both of the plurality of items and the pallet or other receptacle if the plurality of items were stacked on the pallet or other receptacle as simulated in the computer simulation.

According to various embodiments, the system models noise (e.g., noise comprised in sensor data, or noise corresponding to differences between a geometric model and the sensor data). The modelling of noise in connection with determining an estimated state can provide a better final estimate of the state of the system (e.g., a more accurate/precise estimated state). In some embodiments, the system estimates a type/extent of noise (e.g., point cloud noise) corresponding to a destination location at which a particular item is geometrically placed (e.g., where the system assumes the object is placed/to be placed in an idealized state).

The estimated state obtained by robotic system 100 (e.g., control computer 118) reflects the expected noise generated in connection with picking and placing items. For example, the geometric model is updated to account for the expected noise. The updating the geometric model to account for the expected noise can include adjusting the geometric model to include imprecision in the placement of the item as a result of expected noise. The updating the geometric model to account for the expected noise can include adjusting the geometric model to resolve noise comprised in the sensor data such as voids occurring as a result of a blocking of the field of view, or distortions generated by the camera at edges of field of views in the vision system.

In some embodiments, an estimated state of a workspace is obtained by robotic system 100. Robotic system 100 (e.g., control computer 118) uses the estimated state to determine a plan for moving an item such as placing the item among a stack of items. In response to determining the plan for moving the item, robotic system 100 can update a geometric model to reflect the movement (e.g., placement) of the item. As an example, robotic system 100 updates the geometric model based on requesting/instructing a state estimator module/model to reflect the movement of the item. The updated geometric model can be used in connection with determining an updated estimated state. For example, the updated estimated state may correspond to the updated geometric model, or the updated estimated state may correspond to a combination of the updated geometric model and sensor data captured by a vision system. In some embodiments, noise that is expected to be manifested in sensor data or a difference between sensor data and the geometric model (e.g., an inaccurate placement based on a miscalibration of the robotic arm, or inaccurate placement caused by a swaying of the item during the moving, etc.) is modeled. For example, the noise is modeled based on a type/extent of noise that the system expects to be manifested (e.g., based on a destination location of the item placed, an edge of a camera field of view, etc.). In response to modelling the noise (e.g., determining a noise profile), the system can modify (e.g., adjust) the updated estimated state (e.g., the updated geometric model) based at least in part on the expected noise. For example, the state estimation module/model uses the modeled noise to determine the updated estimated state.

In some embodiments, the system may model an adjustment that compensates for the noise. The system may determine the adjustment to be implemented with respect to the estimated state (e.g., the geometric model and/or sensor data) based at least in part on an expected noise (e.g., an expected type of noise and/or an expected extent of such noise, etc.). The adjustment of the estimated state (e.g., to obtain a finalized estimated state) includes adjusting the idealized state of the geometric model to reflect physical reality (e.g., imprecision in placement of items according to a plan, items having rounded/crushed corners, etc.). Robotic system 100 uses the adjusted/updated estimated state (e.g., the finalized estimated state) to determine a plan for moving one or more items.

Although the foregoing example is discussed in the context of a system palletizing a set of items on one or more pallets, the robotic system can also be used in connection with depalletizing a set of items from one or more pallets.

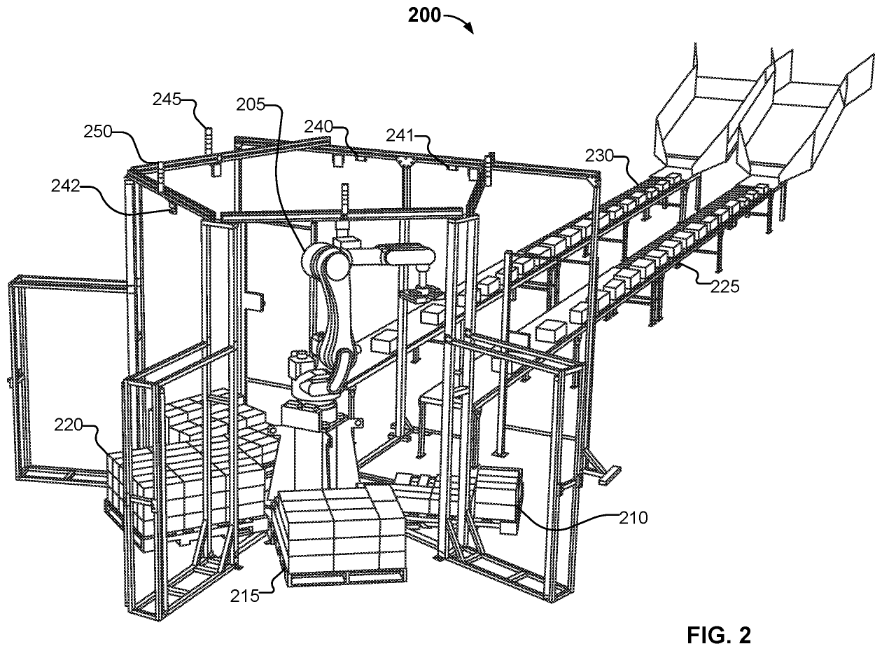

FIG. 2 is a diagram illustrating a robotic system to palletize and/or depalletize heterogeneous items according to various embodiments. In some embodiments, system 200 is implements at least part of process 300 of FIG. 3, process 400 of FIG. 4, process 500 of FIG. 5, process 600 of FIG. 6, process 800 of FIG. 8, process 900 of FIG. 9, process 1000 and/or process 1100.

In the example shown, system 200 includes a robotic arm 205. In this example the robotic arm 205 is stationary, but in various alternative, embodiments robotic arm 205 may be a fully or partly mobile, e.g., mounted on a rail, fully mobile on a motorized chassis, etc. In other implementations, system 200 may include a plurality of robotic arms with a workspace. As shown, robotic arm 205 is used to pick arbitrary and/or dissimilar items from one or more conveyors (or other source) 225 and 230, and the items on a pallet (e.g., platform or other receptacle) such as pallet 210, pallet 215, and/or pallet 220. In some embodiments, other robots not shown in FIG. 2 may be used to push pallet 210, pallet 215, and/or pallet 220 into position to be loaded/unloaded and/or into a truck or other destination to be transported, etc.

As illustrated in FIG. 2, system 200 may comprise one or more predefined zones. For example, pallet 210, pallet 215, and pallet 220 are shown as located within the predefined zones. The predefined zones may be denoted by marking or labelling on the ground or otherwise structurally such as via the frame shown in system 200. In some embodiments, the predefined zones may be located radially around robotic arm 205. In some cases, a single pallet is inserted into a predefined zone. In other cases, one or more pallets are inserted into a predefined zone. Each of the predefined zones may be located within range of robotic arm 205 (e.g., such that robotic arm 205 can place items on a corresponding pallet, or de-palletize items from the corresponding pallet, etc.). In some embodiments, one of the predefined zones or pallets located within a predefined zone is used as a buffer or staging area in which items are temporarily stored (e.g., such as temporary storage until the item is to be placed on a pallet in a predefined zone).

One or more items may be provided (e.g., carried) to the workspace of robotic arm 205 such as via conveyor 225 and/or conveyor 230. System 200 may control a speed of both conveyor 225 and/or conveyor 230. For example, system 200 may control the speed of conveyor 225 independently of the speed of conveyor 230, or system 200 may control the speeds of conveyor 225 and/or conveyor 230. In some embodiments, system 200 may pause conveyor 225 and/or conveyor 230 (e.g., to allow sufficient time for robotic arm 205 to pick and place the items. In some embodiments, conveyor 225 and/or conveyor 230 carries items for one or more manifests (e.g., orders). For example, conveyor 225 and conveyor 230 may carry items for a same manifest and/or different manifests. Similarly, one or more of the pallets/predefined zones may be associated with a particular manifest. For example, pallet 210 and pallet 215 may be associated with a same manifest. As another example, pallet 210 and pallet 220 may be associated with different manifests.

System 200 may control robotic arm 205 to pick an item from a conveyor such as conveyor 225 or conveyor 230, and place the item on a pallet such as pallet 210, pallet 215, or pallet 220. Robotic arm 205 may pick the item and move the item to a corresponding destination location (e.g., a location on a pallet or stack on a pallet) based at least in part on a plan associated with the item. In some embodiments, system 200 determines the plan associated with the item such as while the item is on the conveyor, and system 200 may update the plan upon picking up the item (e.g., based on an obtained attribute of the item such as weight, or in response to information obtained by a sensor in the workspace such as an indication of an expected collision with another item or human, etc.). System 200 may obtain an identifier associated with the item such as a barcode, QR code, or other identifier or information on the item. For example, system 200 may scan/obtain the identifier as the item is carried on the conveyor. In response to obtaining the identifier, system 200 may use the identifier in connection with determining the pallet on which the item is to be placed such as by performing a look up against a mapping of item identifier to manifests, and/or a mapping of manifests to pallets. In response to determining one or more pallets corresponding to the manifest/order to which the item belongs, system 200 may select a pallet on which to place the item based at least in part on a model or simulation of the stack of items on the pallet and/or on a placing of the item on the pallet. System 200 may also determine a specific location at which the item is to be placed on the selected pallet (e.g., the destination location). In addition, a plan for moving the item to the destination location may be determined, including a planned path or trajectory along which the item may be moved. In some embodiments, the plan is updated as the robotic arm 205 is moving the item such as in connection with performing an active measure to change or adapt to a detected state or condition associated with the one or more items/objects in the workspace (e.g., to avoid an expected collision event, to account for a measured weight of the item being greater than an expected weight, to reduce shear forces on the item as the item moved, etc.).

According to various embodiments, system 200 comprises one or more sensors and/or sensor arrays. For example, system 200 may include one or more sensors within proximity of conveyor 225 and/or conveyor 230 such as sensor 240 and/or sensor 241. The one or more sensors may obtain information associated with an item on the conveyor such as an identifier or information on the label of the item, or an attribute of the item such as a dimensions of the item. In some embodiments, system 200 includes one or more sensors and/or sensor arrays that obtain information pertaining to a predefined zone and/or a pallet in the zone. For example, system 200 may include a sensor 242 that obtains information associated with pallet 220 or the predefined zone within which pallet 220 is located. Sensors may include one or more 2D cameras, 3D (e.g., RGBD) cameras, infrared, and other sensors to generate a three-dimensional view of a workspace (or part of a workspace such as a pallet and stack of items on the pallet). The Information pertaining to a pallet may be used in connection with determining a state of the pallet and/or a stack of items on the pallet. As an example, system 200 may generate a model of a stack of items on a pallet based at least in part on the information pertaining to the pallet. System 200 may in turn use the model in connection with determining a plan for placing an item on a pallet. As another example, system 200 may determine that a stack of items is complete based at least in part on the information pertaining to the pallet.

According to various embodiments, system 200 determines a plan for picking and placing an item (or updates the plan) based at least in part on a determination of a stability of a stack on a pallet. System 200 may determine a model of the stack for one or more of pallets 210, 215, and/or 220, and system 200 may use the model in connection with determining the stack on which to place an item. As an example, if a next item to be moved is relatively large (e.g., such that a surface area of the item is large relative to a footprint of the pallet), then system 200 may determine that placing the item on pallet 210 may cause the stack thereon to become unstable (e.g., because the surface of the stack is non-planar). In contrast, system 200 may determine that placing the relatively large (e.g., planar) item on the stack for pallet 215 and/or pallet 220 may result in a relatively stable stack. The top surfaces of the stacks for pallet 215 and/or pallet 220 are relatively planar and the placement of a relatively large item thereon may not result in the instability of the stack. System 200 may determine that an expected stability of placing the item on pallet 215 and/or pallet 220 may be greater than a predetermined stability threshold, or that placement of the item on pallet 215 or pallet 220 may result in an optimized placement of the item (e.g., at least with respect to stability).

System 200 may communicate a state of a pallet and/or operation of the robotic arm 205 within a predefined zone. The state of the pallet and/or operation of the robotic arm may be communicated to a user or other human operator. For example, system 200 may include a communication interface (not shown) via which information pertaining to the state of system 200 (e.g., a state of a pallet, a predetermined zone, a robotic arm, etc.) is communicated to a terminal such as an on-demand teleoperation device and/or a terminal used by a human operator. As another example, system 200 may include a status indicator within proximity of a predefined zone, such as status indicator 245 and/or status indicator 250.

Status indicator 250 may be used in connection with communicating a state of a pallet and/or operation of the robotic arm 205 within the corresponding predefined zone. For example, if system 200 is active with respect to the predefined zone in which pallet 220 is located, the status indicator can so indicate such as via turning on a green-colored light or otherwise communicating information or an indication of the active status via status indicator 250. System 200 may be determined to be in an active state with respect to a predefined zone in response to determining that robotic arm 205 is actively palletizing one or more items on the pallet within the predefined zone. As another example, if system 200 is inactive with respect to the predefined zone in which pallet 220 is located, the status indicator can so indicate such as via turning on a red-colored light or otherwise communicating information or an indication of the active status via status indicator 250. System 200 may be determined to be inactive in response to a determination that robotic arm 205 is not actively palletizing one or more items on the pallet within the predefined zone, for example, in response to a user pausing that predefined zone (or cell), or in response to a determination that a palletization of items on pallet 220 is complete. A human operator or user may use the status indicator as an indication as to whether entering the corresponding predefined zone is safe. For example, a user working to remove completed pallets, or inserting empty pallets, to/from the corresponding predefined zone may refer to the corresponding status indicator and ensure to enter the predefined zone when the status indicator indicates that operation within the predefined zone is inactive.

According to various embodiments, system 200 may use information obtained by one or more sensors within the workspace to determine an abnormal state pertaining to the pallet and/or items stacked on the pallet. For example, system 200 may determine that a pallet is misaligned relative to robotic arm 205 and/or the corresponding predefined zone based at least in part on the information obtained by the sensor(s). As another example, system 200 may determine that a stack is unstable, that items on a pallet are experiencing a turbulent flow, etc. based at least in part on the information obtained by the sensor(s). In response to detecting the abnormal state, system 200 may communicate an indication of the abnormal state such as an on-demand teleoperation device or other terminal used by an operator. In some embodiments, in response to detecting the abnormal state, system 200 may automatically set the pallet and/or corresponding zone to an inactive state. In addition to, or as an alternative to, notifying an operator of the abnormal state, system 200 may perform an active measure. The active measure may include controlling the robotic arm 205 to at least partially correct the abnormal state (e.g., restack fallen items, realign the pallet, etc.). In some implementations, in response to detecting that an inserted pallet is misaligned (e.g., incorrectly inserted to the predefined zone), system 200 may calibrate the process for modelling a stack and/or for placing items on the pallet to correct for the misalignment. For example, system 200 may generate and use an offset corresponding to the misalignment when determining and Implementing a plan for placing an item on the pallet. In some embodiments, system 200 performs the active measure to partially correct the abnormal state in response to determining that an extent of the abnormality is less than a threshold value. Examples of determining that an extent of the abnormality is less than a threshold value include (i) a determination that the misalignment of the pallet is less than a threshold misalignment value, (ii) a determination that a number of dislodged, misplaced, or fallen items is less than a threshold number, (iii) a determination that a size of a dislodged, misplaced, or fallen item satisfies a size threshold, etc.

A human operator may communicate with system 200 via a network such as a wired network and/or a wireless network. For example, system 200 may comprise a communication interface via which system 200 is connected to one or more networks. In some embodiments, a terminal connected via network to system 200 provides a user interface via which a human operator can provide instructions to system 200, and/or via which the human operator may obtain information pertaining to a state of system 200 (e.g., a state of the robotic arm, a state of a particular pallet, a state of a palletization process for a particular manifest, etc.). The human operator may provide an instruction to system 200 via an input to the user interface. For example, a human operator may use the user interface to pause the robotic arm, pause a palletization process with respect to a particular manifest, pause a palletization process for a particular pallet, toggle a status of a pallet/predefined zone between active/inactive, etc.

In various embodiments, elements of system 200 may be added, removed, swapped out, etc. In such an instance, a control computer initializes and registers the new element, performs operational tests, and begins/resumes kitting operations, incorporating the newly added element, for example.

According to various embodiments, system 200 determines (e.g., computes, maintains, stores, etc.) an estimated state for each pallet in the plurality of zones (e.g., pallet 210, pallet 215, and/or pallet 220), or an aggregated estimated state for the set of pallets among the plurality of zones, or both individual estimated states and an aggregated estimated state. In some embodiments, the individual estimated states and an aggregated estimated state are determined similar to the estimated state described in connection with robotic system 100 of FIG. 1.

According to various embodiments, system 200 comprises a vision system comprising one or more sensors (e.g., sensor 240, sensor 241, etc.). In various embodiments, system 200 uses sensor data and geometric data (e.g., a geometric model) in connection with determining a location at which to place one or more items on a pallet (or in connection with depalletizing one or more items from a pallet). System 200 uses different data sources to model the state of a pallet (or a stack of items on a pallet). For example, system 200 estimates locations of one or more items on the pallet(s) and one or more characteristics (or attributes) associated with the one or more items (e.g., a size of the item(s)). The one or more characteristics associated with the one or more items may include an item size (e.g., dimensions of the item), a center of gravity, a rigidity of the item, a type of packaging, a location of an identifier, etc.

System 200 determines the geometric model based at least in part on one or more attributes for one or more items in the workspace. For example, the geometric model reflects respective attributes of a set of items (e.g., one or more of a first set that are palletized/stacked, and a second set of items that is to be palletized/stacked, etc.). Examples of attributes for an item include an item size (e.g., dimensions of the item), a center of gravity, a rigidity of the item, a type of packaging, a location of an identifier, a deformability of the item, a shape of the item, etc. Various other attributes of an item or object within the workspace may be implemented.

The model generated by system 200 can correspond to, or be based at least in part on, a geometric model. In some embodiments, system 200 generates the geometric model based at least in part on one or more items that have been placed (e.g., items for which system 200 controlled robotic arm 205 to place), one or more attributes respectively associated with at least a subset of the one or more items, one or more objects within the workspace (e.g., predetermined objects such as a pallet, a robotic arm(s), a shelf system, a chute, or other infrastructure comprised in the workspace). The geometric model can be determined based at least in part on running a physics engine on control computer to model a stacking of items (e.g., models a state/stability of a stack of items, etc.). The geometric model can be determined based on an expected interaction of various components of the workspace, such as an item with another item, an object, a simulated force applied to the stack (e.g., to model the use of a forklift or other device to raise/move a pallet or other receptacle on which a stack of items is located).

According to various embodiments, system 200 uses the geometric model and the sensor data to determine a best estimate of a state of the workspace. System 200 can adjust for (e.g., cancel) noise in one or more of the geometric model and/or sensor data. In some embodiments, system 200 detects anomalies or differences between a state according to the geometric model and a state according to the sensor data. In response to determining an anomaly or difference between the geometric model and the sensor data, system 200 can make a best estimate of the state notwithstanding the anomaly or difference. For example, system 200 determines whether to use the geometric model or the sensor data, or a combination of (e.g., an interpolation between) the geometric model and the sensor data, etc. In some embodiments, system 200 determines the estimated state on a segment-by-segment basis (e.g., a voxel-by-voxel basis in the workspace, an item-by-item basis, or an object-by-object basis, etc.). For example, a first part of the workspace may be estimated using only the geometric model, a second part of the workspace may be estimated using only the sensor data (e.g., in the event of an anomaly in the geometric model), and/or a third part of the workspace may be estimated based on a combination of the geometric model and the sensor data. Using the example illustrated in FIG. 2, in connection with determining an aggregated estimated state, system 200 may use only the geometric model to determine the individual estimated state for the stack of items on pallet 210, use only sensor data to determine the individual estimated state for the stack of items on pallet 215, and use a combination of the respective geometric model and sensor data for the stack of items on pallet 220.

The estimated state obtained by system 200 reflects the expected noise generated in connection with picking and placing items. For example, the geometric model is updated to account for the expected noise. The updating the geometric model to account for the expected noise can include adjusting the geometric model to include imprecision in the placement of the item as a result of expected noise. The updating the geometric model to account for the expected noise can include adjusting the geometric model to resolve noise comprised in the sensor data such as voids occurring as a result of a blocking of the field of view, or distortions generated by the camera at edges of field of views in the vision system.

According to various embodiments, system 200 models noise (e.g., noise comprised in sensor data, or noise corresponding to differences between a geometric model and the sensor data). The modelling of noise in connection with determining an estimated state can provide a better final estimate of the state of the system (e.g., a more accurate/precise estimated state). In some embodiments, system 200 estimates a type/extent of noise (e.g., point cloud noise) corresponding to a destination location at which a particular item is geometrically placed (e.g., where the system assumes the object is placed/to be placed in an idealized state). In some embodiments, the modelling the noise includes performing a machine learning process to train a noise profile (e.g., a noise model).

Various simulations performed with respect to determining an estimated state or a plan for moving a set of items (e.g., a plan to palletize a set of items) include varying a state estimation model. Varying the state estimation model can include varying a stacking model according to which the set of items are moved. In some embodiments, varying the stacking model may include varying one or more of an order in which the set of items are moved, a location of one or more of the set of items, an orientation of the one or more set of items, a noise profile used in modelling placement of the set of items, etc. Varying the state estimation model can include varying settings or configurations of the model. In some embodiments, varying settings or configurations includes varying a cost function, one or more thresholds used in connection with modelling a set of items such as a stack of items (e.g., a stability threshold, a time threshold, a bias for placing items with certain attributes in certain locations (e.g., placing larger items at a bottom of a stack of items), a range of acceptable locations or orientations for certain items (e.g., a defined set of locations or orientations according to which items having certain attribute(s) are permitted to be placed), etc).

According to various embodiments, performing simulations to determine the state estimation model, or the estimated state, includes simulating movement of a set of items according to a set of different item ordering in which items are moved. For example, the system performs a first simulation of stacking a set of items according to a first order in which the set of items are stacked, and the system performs a second simulation of stacking the set of items according to a second order in which the set of items are stacked, etc.

According to various embodiments, the simulations performed to determine the state estimation model, or the estimated state, includes simulating movement of a set of items according to a set of different locations and/or orientations for which the items are moved. For example, the system performs a first simulation of stacking a set of items at a corresponding first set of item locations and/or orientations, and the system performs a second simulation of stacking a set of items at a corresponding first set of item locations and/or orientations, etc.

According to various embodiments, the simulating the state estimation model include varying one or more environmental factors. Examples of environmental factors that are varied/simulated during the simulations includes dust, glare from items or other objects in the workspace, humidity, number of pallets on which items may be stacked, etc.

Although the foregoing example is discussed in the context of a system palletizing a set of items on one or more pallets, the robotic system can also be used in connection with depalletizing a set of items from one or more pallets.

In some embodiments, the system determines a state estimation model based at least in part on the simulations (e.g., the set of state estimation models generated via the simulation). The state estimation model used by the system to determine an estimated state may correspond to one of the state estimation models generated via the simulations, or may be determined based on a combination of two more of the state estimation models generated via the simulations.

In some embodiments, the system evaluates the state estimation models generated via the simulations and uses results of the evaluation to determine one or more characteristics or configurations that yields a best result. As an example, the best result corresponds to a set of characteristics or configurations that provide a quickest estimation of the state given the noise data. As another example, the best result corresponds to a state estimation that is most accurate (e.g., as determined based on empirical trials). In some embodiments, the state estimation model that yields the best result is determined based on a value for a cost function applied with respect to the set of state estimation models generated via the simulations. For example, the state estimation model yielding the best result (e.g., the best state estimation model) is a state estimation model for which a value of the cost function is lowest. The cost function can be based at least in part on one or more of an accuracy, a time for providing an estimation (e.g., the amount of time the state estimation model requires to provide an estimated state), a number of factors considered in the state estimation model, an inclusion or exclusion of one or more predefined factors, etc. Various other variables may be implemented in the cost function.

FIG. 3 is a flow chart illustrating a process to palletize one or more items according to various embodiments. In some embodiments, process 300 is implemented at least in part by robotic system 100 of FIG. 1 and/or system 200 of FIG. 2.

At 310, a list of items is obtained. The list of items may correspond to a set of items that are to be collectively palletized on one or more pallets. According to various embodiments, a set of items to be palletized is determined based at least in part on an indication that a manifest or order is to be fulfilled. For example, in response to receiving an order, a list of items for the order may be generated. As another example, a list of items corresponding to a plurality of orders to be sent to the same recipient may be generated.

The items may be located on a shelf or other location within a warehouse. In order to palletize the items, the items are moved to a robotic system that palletizes the items. For example, the items may be placed on one or more conveyors that move the items to within range of one or more robotic arms that palletize the items onto one or more pallets. In response to obtaining the list of items, at least some of the items are associated with a particular robotic arm, a predefined zone corresponding to the particular robotic arm, and/or a particular pallet (e.g., a pallet identifier, a pallet located in a predefined zone), etc.

At 320, planning (or re-planning) is performed to generate a plan to pick/place items based on the list of items and available sensor information. The plan may include a one or more strategies for retrieving one or more items on the list of items and placing such items on the corresponding one or more conveyors to carry the items to a robotic arm. According to various embodiments, an order in which the items on the list of items are to be provided to the applicable robotic arm for palletizing is determined based at least in part on the list of items.

In some embodiments, generating the plan includes querying a state estimation model. The state estimation model may be predefined and selected from among a set of state estimation models (e.g., the set of state estimation modules may be obtained based on a set of computer simulations). In some embodiments, the system queries the state estimation model based at least in part on sensor data and/or the geometric model (e.g., the previous estimated state that is adjusted to reflect a movement of one or more items since the estimated state was determined). For example, the system sends to a state estimation module the sensor data and the geometric model (or identifiers of the sensor data and geometric model that can be used to retrieve such information from a remote storage), and the state estimation module uses the sensor data and the geometric model to query a state estimation model.

The order in which the items are placed on the conveyor may be at least loosely based on the items and an expected stack of the items on one or more pallets. For example, the system determining the order in which to place the items on the conveyor may generate a model of an expected stack(s) of the items, and determine the order based on the model (e.g., so as to first deliver items that form the base/bottom of the stack and progressively deliver items higher up the stack). In the case that the items on the list of items are to be palletized on a plurality of pallets, items that are expected to form the base/bottom of the respective stacks (or otherwise be relatively near the bottom of the stacks) may be placed on the conveyor before items that are expected to be substantially in the middle or top of the stacks. Various items that are to be palletized on the plurality of pallets may be interspersed among each other and the robotic system may sort the items upon arrival at the robotic arm (e.g., the robotic arm may pick and place the items onto an applicable pallet based at least on the item such as the identifier of the item or an attribute of the item). Accordingly, the items corresponding to the base/bottom portion of the corresponding stacks may be interspersed among each other and various items for each pallet/stack may be placed on the conveyor as the corresponding stack is built.

The computer system may generate a model of one or more expected stacks for the items belonging to the list of items. The model may be generated based at least in part on one or more thresholds such as a fit threshold value or stability threshold value, other packing metric (e.g., density), etc. For example, the computer system can generate a model of a stack for which an expected stability value satisfies (e.g., exceeds) the stability threshold value. The model may be generated using a machine learning process. The machine learning process may be iteratively updated based on historical information such as previous stacks of items (e.g., attributes of items in previous stacks, performance metrics pertaining to the previous stacks such as stability, density, fit, etc.). In some embodiments, the model of the stack(s) for palletizing the items on the list of items is generated based at least in part on one or more attributes of the items.

Various attributes of an item may be obtained before or during the determining of the plan. Attributes may include a size of an item, a shape of an item, a type of packaging of an item, an identifier of an item, a center of gravity of an item, an indication of whether the item is fragile, an indication of a top or bottom of the item, etc. As an example, one or more attributes pertaining to at least a subset of the items may be obtained based at least in part on the list of items. The one or more attributes may be obtained based at least in part on information obtained by one or more sensors, and/or by performing a lookup in a mapping of attributes to items (e.g., item types, item identifiers such as serial numbers, model numbers, etc.).

In some embodiments, the generating the model of one or more expected stacks for the items belonging to the list of items includes generating (e.g., determining) an estimated state for the workspace (e.g., a workspace comprising one or more stacks of items). The computer system determines a plan for moving (e.g., palletizing or depalletizing, etc.) a set of one or more items, and the computer system controls a robot (e.g., a robotic arm) to move the set of one or more items according to the plan. In response to moving the set of one or more items according to the plan, the computer system determines an estimated state for the workspace. For example, the computer system updates the estimated state based at least in part on the movement of the set of items. In some embodiments, the estimated state is determined based at least in part on the geometric model or the sensor data, or a combination of the geometric model and the sensor data in response to a determination that the geometric model and the sensor data are incongruent (e.g., that a difference between the geometric model and the sensor data is greater than a predetermined difference threshold, or comprise an anomaly, etc.). The updated/current estimated state reflects the movement of the set of one or more items (e.g., in the case of palletizing, the updated estimated state includes information pertaining to the placement of the set of one or more items on the stack(s), etc.). In response to determining the updated/current estimated state, the computer system determines a plan for moving another set of one or more items, and the computer system controls the robot to move the other set of one or more items according to the plan.

In some embodiments, the computer system updates the current state (e.g., updates based on an update to the geometric model) after (i) movement (e.g., placement) of a predetermined number of items, or (ii) the earlier of movement of the predetermined number of items or detection of an anomaly such as an anomaly that satisfies one or more anomaly criteria (e.g., the extent of the anomaly exceeds an anomaly threshold, etc.). The predetermined number of items (e.g., X items, X being a positive integer) can be set based on user preferences, a robot control system policy, or otherwise determined based on empirical analysis of placement of items. As an example, the predetermined number of items is set based on a determination that the number of items results in an optimal/best result with respect to a predetermined cost function (e.g., a cost function reflecting an efficiency, a stability, expected change in stability, etc.). As an example, the computer system determines a current estimated state and uses the current estimated state to determine a plan for moving the next X items, and after moving the X items (e.g., the stacking or de-stacking of the items), the computer system determines an updated estimated state (e.g., a geometric update/model to reflect placement of the X items). The computer system determines the updated state based at least in part on a combination of the geometric model and the sensor data (e.g., a current geometric model and current sensor data, etc.). The computer system then uses the updated state in connection with determining a plan and controlling a robotic to place a next set of items in accordance with the plan.

According to various embodiments, the computer system determines the estimated state based at least in part on performing an interpolation between the geometric model and the sensor data. For example, the system performs the interpolation for a particular part of a geometric model and a corresponding part of the sensor data (e.g., the particular part may correspond to a difference between the geometric model and the sensor data that exceeds a difference threshold, or comprises an anomaly).

Various interpolation techniques may be implemented. The particular part of the geometric model may correspond to a particular point (or set of points) in the point cloud for the geometric model, and the corresponding part of the sensor data may be the sensor data for that particular point in the point cloud for the sensor data, etc. In some embodiments, the system performs an adaptive interpolation between the geometric model and the sensor data. In some embodiments, the system performs a non-adaptive interpolation between the geometric model and the sensor data. Examples of adaptive interpolation processing include: nearest neighbor, bilinear, bicubic, spline, sinc, lanczos, etc. Various other interpolation processing may be performed in connection with determining an estimated state.

At 330, items are picked and moved through a (predetermined/planned) trajectory to a location near where the item is to be placed on the corresponding conveyor, and placed at the destination location according to the plan determined and/or updated at 320.

In the example shown, (re-)planning and plan implementation (320, 330) continue until the high level objective of providing the items on the list of items is completed (340), at which the process 300 ends. In various embodiments, re-planning (320) may be triggered by conditions such as the arrival of items that are not expected and/or cannot be identified, a sensor reading indicating an attribute has a value other than what was expected based on item identification and/or associated item model information, etc. Other examples of unexpected conditions include, without limitation, determining that an expected item is missing, reevaluating item identification and determining an item is other than as originally identified, detecting an item weight or other attribute inconsistent with the item as identified, dropping or needing to re-grasp the item, determining that a later-arriving item is too heavy to be stacked on one or more other items as contemplated by the original and/or current plan, and detecting instability in the set of items as stacked on the receptacle.

FIG. 4 is a flow chart illustrating a process to simulate movement of a set of items according to various embodiments. In some embodiments, process 400 is implemented at least in part by robotic system 100 of FIG. 1 and/or system 200 of FIG. 2.

In some embodiments, process 400 is invoked in connection with simulating a state estimation model. For example, a plurality of iterations of process 400 can be performed in connection with determining a set of state estimation modules that are to be evaluated and from which a selected state estimation model is to be selected (e.g., a best state estimation model). The various iterations may be unique among the various iterations (e.g., an order of items is varied, a parameter of a state estimation model is varied, a stacking technique is varied, destination locations of the respective items are varied, orientations of the respective items are varied, a noise profile(s) is varied, etc.). In some embodiments, two or more of the plurality of iterations of process 400 are implemented in parallel.

In some embodiments, process 400 is invoked during a palletizing or de-palletizing of a set of items. For example, if a palletization process is underway, process 400 may be invoked to determine a state estimation model to implement to simulate stacking of a next N items, etc.

At 410, a set of items is obtained. In some embodiments, the set of items corresponds to items comprised on a manifest for an order. In some embodiments, the system randomly picks the set of items from among a predefined set of items. In some embodiments, the system determines attributes for items for which a palletization simulation is to be performed. For example, the system may vary one or more attributes among items in the set of items.

At 420, geometric data associated with the pallet/stack of items is determined. In some embodiments, the system obtains the geometric model of the workspace.

At 430, noise is used to adjust the geometric data. In some embodiments, the system determines (e.g., selects) one or more noise profiles for noise to be introduced in connection with a simulation of the picking and placing of the item(s). The system adjusts the geometric model to account for the noise profile. As an example, with respect to noise corresponding to a simulated sway of items during movement (e.g., a noise in the placement of the item as a result of the sway) is used to adjust the placement of the item.

In some embodiments, rather than obtaining the geometric model and then adjusting the geometric model to account for (e.g., reflect) a noise profile, the system generates the geometric model by modelling/simulating placement of an item in accordance with the noise profile. For example, without noise being used in the generating of the geometric model, the location and orientation of the item(s) is precisely in accordance with the plan for placing the item(s) (e.g., the system assumes the robotic arm precisely places the item). However, accounting for the noise includes determining a placement location corresponding to an item's destination location adjusted for noise.

At 440, a current state of a pallet/stack of items is estimated using a state estimation model. In some embodiments, the system determines an estimated state. The estimated state may correspond to the geometric model or a geometric model adjusted for noise. In some embodiments, the system queries the state estimation model based at least in part on the geometric model.

At 450, a plan to pick and place an item is determined based at least in part on current state. In some embodiments, the system uses the estimated state to determine a plan for moving the item to a destination location.

At 460, picking and placing the item is simulated. The system simulates the picking and placing the item(s) in accordance with the plan. In some embodiments, the system simulates the picking and placing the item(s) in accordance with the plan as adjusted according to a noise profile. For example, the system applies a noise that corresponds to modeled noise profile corresponding to a sway of the item during movement.

At 470, a determination is made as to whether more items from the set of items is to be picked and placed. In response to determining that more items are to be picked and placed, process 400 returns to 420 and process iterates over 420-470 until no further items from the set of items are to be picked and placed.

At 475, the state estimation model is evaluated. In some embodiments, the system determines a goodness of the state estimation model. For examples, the system compares the state estimation model to other state estimation model(s) to determine a best state estimation model, or to determine a state estimation model that is among a certain percentile of state estimation models. In some embodiments, the system applies a cost function to determine the goodness of the state estimation model. For example, the system uses a cost function to compute a cost associated with the state estimation model.

FIG. 5 is a flow chart illustrating a process to simulate movement of a set of items according to various embodiments. In some embodiments, process 500 is implemented at least in part by robotic system 100 of FIG. 1 and/or system 200 of FIG. 2.

According to various embodiments, process 500 is implemented in connection with simulating a plurality of state estimation models such as in connection with obtaining a best state estimation model.

At 505, a set of items is obtained. In some embodiments, the set of items corresponds to items comprised on a manifest for an order. In some embodiments, the system randomly picks the set of items from among a predefined set of items. In some embodiments, the system determines attributes for items for which a palletization simulation is to be performed. For example, the system may vary one or more attributes among items in the set of items.

At 510, a state estimation model is selected. In some embodiments, the system determines the state estimation model according to which the simulation corresponding to the particular iteration is to be performed.

At 515, geometric data associated with the pallet/stack of items is determined. In some embodiments, the system obtains the geometric model of the workspace.

At 520, noise is used to adjust the geometric data. In some embodiments, the system determines (e.g., selects) one or more noise profiles for noise to be introduced in connection with a simulation of the picking and placing of the item(s). The system adjusts the geometric model to account for the noise profile. As an example, with respect to noise corresponding to a simulated sway of items during movement (e.g., a noise in the placement of the item as a result of the sway) is used to adjust the placement of the item.

In some embodiments, rather than obtaining the geometric model and then adjusting the geometric model to account for (e.g., reflect) a noise profile, the system generates the geometric model by modelling/simulating placement of an item in accordance with the noise profile. For example, without noise being used in the generating of the geometric model, the location and orientation of the item(s) is precisely in accordance with the plan for placing the item(s) (e.g., the system assumes the robotic arm precisely places the item). However, accounting for the noise includes determining a placement location corresponding to an item's destination location adjusted for noise.

At 525, a current state of a pallet/stack of items is estimated using a state estimation model. In some embodiments, the system determines an estimated state. The estimated state may correspond to the geometric model or a geometric model adjusted for noise. In some embodiments, the system queries the state estimation model based at least in part on the geometric model.

At 530, a plan to pick and place an item is determined based at least in part on current state. In some embodiments, the system uses the estimated state to determine a plan for moving the item to a destination location.

At 535, picking and placing the item is simulated. The system simulates the picking and placing the item(s) in accordance with the plan. In some embodiments, the system simulates the picking and placing the item(s) in accordance with the plan as adjusted according to a noise profile. For example, the system applies a noise that corresponds to modeled noise profile corresponding to a sway of the item during movement.

At 540, a determination is made as to whether an additional item from the set of items is to be picked and placed. In response to determining that an additional item(s) are to be picked and placed, process 500 returns to 515 and process iterates over 515-540 until no further items from the set of items are to be picked and placed. In response to determining that no further items are to be picked and placed, process 500 proceeds to 545.

At 545, a determination is made as to whether more state estimation models are to be simulated. In some embodiments, the system determines whether any additional state estimation models are to be simulated in order to include the corresponding result in a set of results with which the various state estimation models are to be evaluated. In response to determining that more state estimation models are to be simulated/evaluated, process 500 returns to 510 and process iterates over 510-545 until no further state estimation models are to be evaluated. In response to determining that no further items are to be picked and placed, process 500 proceeds to 550.

At 550, the state estimation model is evaluated. In some embodiments, the system determines a goodness of the state estimation model. For examples, the system compares the state estimation model to other state estimation model(s) to determine a best state estimation model, or to determine a state estimation model that is among a certain percentile of state estimation models. In some embodiments, the system applies a cost function to determine the goodness of the state estimation model. For example, the system uses a cost function to compute a cost associated with the state estimation model.

In some embodiments, the system determines the state estimation model that yields a best result such as a state estimation model that has a lowest cost according to a predefined cost function, etc. In some embodiments, the system determines one or more characteristics or configurations that yields a best result. For example, the system may deem the characteristics or configurations (e.g., item location, item orientation, order in which items are placed, placing strategy, etc.) of the best state estimation model as being the one or more characteristics or configurations that yields a best result.

FIG. 6 is a flow chart illustrating a process to simulate movement of a set of items according to various embodiments. In some embodiments, process 600 is implemented at least in part by robotic system 100 of FIG. 1 and/or system 200 of FIG. 2.

According to various embodiments, process 600 is implemented in connection with simulating a plurality of state estimation models such as in connection with obtaining a best state estimation model, or determining a set of one or more characteristics or configurations that yield a best result.

At 605, a request for an estimated state is received.

At 610, a state estimation model is selected. In some embodiments, the system determines the state estimation model according to which the simulation corresponding to the particular iteration is to be performed.

At 615, geometric data associated with a pallet and a set of items or a stack of items is determined. For example, the system determines one or more attributes associated with the set of items, the stack of items, the pallet, etc. The system may use the one or more attributes in connection with determining a geometric model, determining an impact of the noise profile on placement/location of the item, and/or simulating picking and placing items.

At 620, a noise profile is selected and used to adjust the geometric data. In some embodiments, the system determines one or more noise profiles that the system expects to impact picking and placing of items in the workspace. Examples of the noise profiles include a sway noise profile, a robot miscalibration noise profile, a glare noise profile, a field of view edge distortion noise profile, an item boundary noise profile, etc. In some embodiments, the system determines (e.g., selects) one or more noise profiles for noise to be introduced in connection with a simulation of the picking and placing of the item(s). The system adjusts the geometric model to account for the noise profile. As an example, with respect to noise corresponding to a simulated sway of items during movement (e.g., a noise in the placement of the item as a result of the sway) is used to adjust the placement of the item.

In some embodiments, rather than obtaining the geometric model and then adjusting the geometric model to account for (e.g., reflect) a noise profile, the system generates the geometric model by modelling/simulating placement of an item in accordance with the noise profile. For example, without noise being used in the generating of the geometric model, the location and orientation of the item(s) is precisely in accordance with the plan for placing the item(s) (e.g., the system assumes the robotic arm precisely places the item). However, accounting for the noise includes determining a placement location corresponding to an item's destination location adjusted for noise.

At 625, a stacking model is selected. In some embodiments, the system determines a stacking model to implement in connection with simulating the state estimation model. The stacking model can correspond to one or more of a preference for placing large items at bottom of a stack (or within a threshold distance of the bottom), a preference to put deformable or non-rigid items at the top of the stack (or within a threshold distance of the top), etc.

At 630, the picking and placing of the set of items is simulated. In some embodiments, the system simulates the picking and placing the set of items in accordance with the stacking model, the noise profile(s), and the state estimation model. For example, the system simulates a stacking of a set of items on a pallet based on the state estimation model, the expected noise profiles that impact the placement of items, and the stacking model. The system uses the noise profile to model a location of the item (e.g., the placement of the item in the geometric model).

At 635, an estimated state is determined. The system determines the geometric model based on the simulation of the picking and placing the set of items.

At 640, a determination is made as to whether more stacking models are to be simulated. In response to determining that more stacking models are to be simulated, process 600 returns to 625 and process iterates over 625-640 until no further stacking models are to be simulated with respect to the state estimation model. In response to determining that no further items are to be picked and placed, process 600 proceeds to 645.

At 645, a determination is made as to whether more state estimation models are to be simulated/evaluated. In response to determining that more state estimation models are to be simulated, process 600 returns to 610 and process iterates over 610-645 until no further state estimation models are to be simulated/evaluated. In response to determining that no state estimation models are to be simulated/evaluated, process 600 proceeds to 650.

At 650, the state estimation model is evaluated. In some embodiments, the system determines a goodness of the state estimation model. For examples, the system compares the state estimation model to other state estimation model(s) to determine a best state estimation model, or to determine a state estimation model that is among a certain percentile of state estimation models. In some embodiments, the system applies a cost function to determine the goodness of the state estimation model. For example, the system uses a cost function to compute a cost associated with the state estimation model.

In some embodiments, the system determines the state estimation model that yields a best result such as a state estimation model that has a lowest cost according to a predefined cost function, etc. In some embodiments, the system determines one or more characteristics or configurations that yields a best result. For example, the system may deem the characteristics or configurations (e.g., item location, item orientation, order in which items are placed, placing strategy, etc.) of the best state estimation model as being the one or more characteristics or configurations that yields a best result.

At 655 a result of the evaluation of the state estimation models is provided. In some embodiments, the system provides an indication of a best state estimation model. In some embodiments, the system provides the state estimation model to another module, service, or system that provides estimated states to a robotic system that is planning the picking and placing of a set of items.

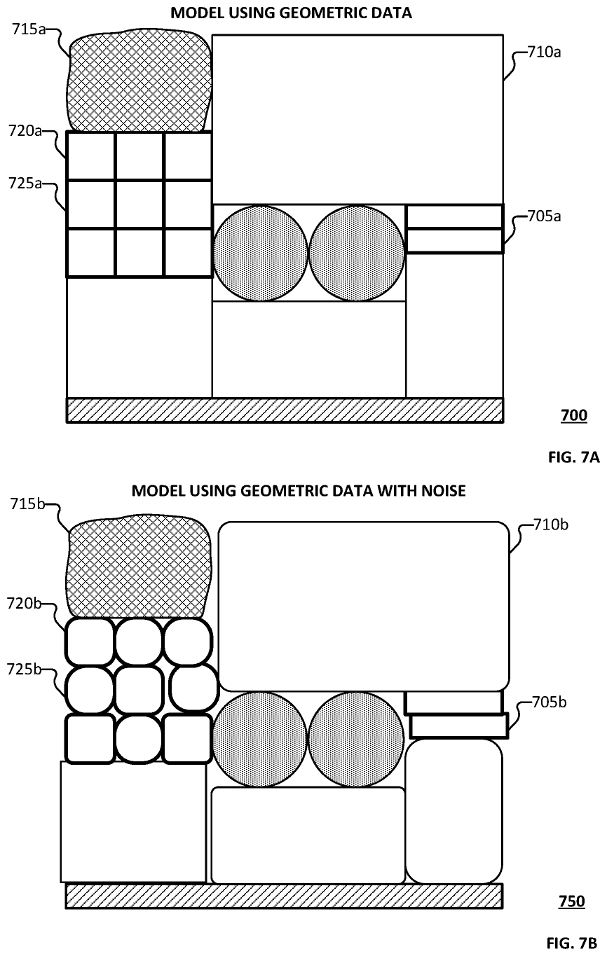

FIG. 7A is a diagram of an idealized state using geometric data according to various embodiments. FIG. 7B is a diagram of an idealized state using geometric data according to various embodiments.

As illustrated in FIG. 7A, pallet 700 illustrates an estimated state of a stack of items in which the system assumes that a robotic arm picks and places the set of items precisely in accordance with a plan for stacking the items. For example, the system determines the estimated state based on the placement of items according to the geometric model. As illustrated in FIG. 7B, pallet 750 illustrates an estimated state in which a noise profile is used to adjust the geometric model. For example, pallet 750 comprises imprecision among the set of items based on noise generated during the stacking of the items or imprecision based on noise in the sensor data used to generate the model of pallet 750.

Pallet 700 comprises item 705a and pallet 750 comprises corresponding item 705b. As illustrated in FIGS. 7A and 7B, item 705b is not precisely stacked above/below the corresponding items in pallet 750. For example, item 705b is offset with respect to the pallet as compared with item 705a which is precisely placed according to the corresponding plan. As another example, the idealized state of pallet 700 comprises item 715a placed next to (and touching) item 710a. However, pallet 750 comprises item 715b placed a certain distance away from item 710b. The system has modeled placement of item 715b with noise such as noise corresponding to a sway of the item during movement (which may impact the precise location at which the item is dropped from the end effector), or movement of the item during placement of another item, etc.

Pallet 750 comprises items in which the edges or corners are not precisely rectangular. In the idealized geometric model, pallet 700 comprises items with squared corners/edges. However, items generally have non-squared corners/edges that may result from the items being deformed, or the box/packaging being imperfect. As an example, 710b is modeled to have rounded corners/edges based on the introduction of noise (e.g., a noise profile for the shape of items) and 710a is modeled to have squared corners/edges. As another example, 720b and 725b are modeled to have rounded corners/edges or non-squared shapes based on the introduction of noise (e.g., a noise profile for the shape of items) and 720a and 725a is modeled to have squared corners/edges.

FIG. 8 is a flow diagram illustrating an embodiment of a determining an estimate of a state of a pallet and/or stack of items. In some embodiments, process 800 is implemented at least in part by robotic system 100 of FIG. 1 and/or system 200 of FIG. 2.

In some embodiments, process 800 is implemented by one or more of an app 802 running on a control system for a robotic arm, server 804, state estimator 806, vision system 808, and placement determiner 810.

At 820, app 802 sends a request to server 804. The request can correspond to a placement request for a plan and/or strategy for placing an item.

In response to receiving the placement request, at 822, server 804 invokes a state determination. For example, server 804 sends a request or instruction to state estimator 806 to determine (and provide) the estimated state. In some embodiments, state estimator 806 is a module running on server 804. In some embodiments, state estimator 806 is a service that is queried by a plurality of different servers/robotic systems. For example, state estimator 806 may be a cloud service.

In response to invoking the state determination, state estimator 806 obtains the vision state. In some embodiments, state estimator 806 sends to vision system 808 a request for a vision state.

In response to receiving the request for the vision state at 824, at 826 vision system 808 provides the vision state to state estimator 806. For example, in response to receiving the request for the vision state, vision system 808 uses one or more sensors in a workspace to capture a snapshot of the workspace.

In response to receiving the vision state, state estimator 806 determines the pallet state (e.g., an estimated state of the pallet and/or stack of items). State estimator 806 may determine the estimated state based on one or more of a geometric model and the vision state. In some embodiments, state estimator 806 combines the geometric model and the vision state (at least with respect to a part of the stack).

At 828, state estimator 806 provides the pallet state to server 804.

At 830, server 804 sends a placement request comprising the pallet state to placement determiner 810. In some embodiments, placement determiner 810 is a module running on server 804. In some embodiments, placement determiner 810 is a service that is queried by a plurality of different servers/robotic systems. For example, placement determiner 810 may be a cloud service.

At 832, placement determiner 810 provides a set of one or more potential placements to server 804. The set of one or more potential placements may be determined based at least in part on an item(s) to be placed (e.g., attributes associated with the item) and the pallet state (e.g., available locations and attributes of items within the stack of items), etc.

In some embodiments, the set of one or more potential placements is a subset of all possible placements. For example, placement determiner 810 uses a cost function to determine the set of one or more potential placements to provide to server 804. Placement determiner 810 may determine potential placements that satisfy a cost criteria (e.g., have a cost less than a cost threshold) with respect to the cost function.

In response to receiving the set of one or more potential placements, at 834, server 804 selects a placement and sends the selected placement to app 802. For example, the selected placement is provided as a response to the initial placement request at 820.

At 836, app 802 controls a robotic arm to place the item. In some embodiments, app 802 determines a plan to move the item to the selected placement (e.g., based on an attribute(s) of the item and the location corresponding to the selected placement, such as coordinates in the workspace).

At 838, app 802 provides an indication to server 804 to perform an update with respect to the geometric state. For example, app 802 provides confirmation that the placement of the item was performed at 836 and server 804 deems such confirmation to be an indication that an update to the geometric state (e.g., geometric model) is to be invoked.

At 840, server 804 sends to state estimator 806 a request to update the geometric state. For example, server 804 requests that state estimator 806 update the geometric model to reflect placement of the item in accordance with the corresponding plan.

In response to receiving the request to update the geometric state, state estimator 806 performs the corresponding update. At 842, state estimator 806 provides an indication to server 804 that the geometric state was successfully updated.

At 844, server 804 provides to app 802 an indication that the geometric state was successfully updated to reflect placement of the item.

Process 800 may be repeated for a set of items to be stacked.

FIG. 9 is a flow diagram illustrating a process of determining an estimated state according to various embodiments. In some embodiments, process 900 is implemented at least in part by robotic system 100 of FIG. 1 and/or system 200 of FIG. 2.

In some embodiments, process 900 is implemented by one or more of server 902, state estimator 904, state storage 906, vision system 908, and filtering module 910.

At 920, server 902 communicates a request for an estimated state to state estimator 904. In some embodiments, server 902 sends the request for the estimated state in connection with determining a plan for picking/placing one or more items.

At 922, in response to receiving the request for the estimated state, state estimator 904 requests the vision state from vision system 908. In some embodiments, state estimator 904 requests the sensor data captured (e.g., contemporaneously) by the vision system.

At 924, vision system 908 returns the vision state. In response to receiving the request for the vision state, the vision system 908 provides state estimator 904 with the sensor data.

In some embodiments, 922 and 924 may be omitted in implementations according to which the system does not comprise vision system 908 or in implementations according to which the vision state (e.g., the sensor data) is not used in connection with determining an estimated state.

At 926, state estimator 904 requests a current estimated state from state storage 906. State storage 906 may store previously computed estimated states. The current estimated state can correspond to the updated geometric state/model after placement of a preceding item (if any).

At 928, state storage 906 provides state estimator with the current estimated state.

At 930, state estimator 904 requests filtering module 910 to combine the geometric model and the sensor data. For example, filtering module 910 can determine an estimated state based on a combination of the geometric model and the sensor data. In some embodiments, filtering module 910 determines the estimated state based at least in part on performing an interpolation with respect to at least part of the geometric model and at least part of the sensor data.

At 932, filtering module 910 provides state estimator 904 with the updated estimated state.

At 934, state estimator 904 sends the updated estimated state to state storage 906 in connection with a request for state storage 906 to store the updated estimated state.

At 936, state estimator 904 provides the estimated state to server 902, such as a response to the request for the estimated state communicated at 920.

At 938, server 902 receives a request to update the geometric state. In some embodiments, a robotic system communicates a request for server 902 to update the geometric state (e.g., the geometric model) in response to placement of one or more items (e.g., after each placement, after placement of N items, and/or in response to determination that an update criteria is satisfied such as placement of an irregularly shaped item, etc.).

At 940, server 902 sends a request to update the geometric state to state estimator 904.

At 942, state estimator updates the geometric state (e.g., the geometric model) to account for placement of the item(s), and sends the updated geometric state to state storage 906 for storage.

At 944, state storage 906 provides confirmation that the updated geometric state has been successfully stored/updated.

At 946, state estimator 904 provide confirmation to server 902 that the update to the geometric state is successful.

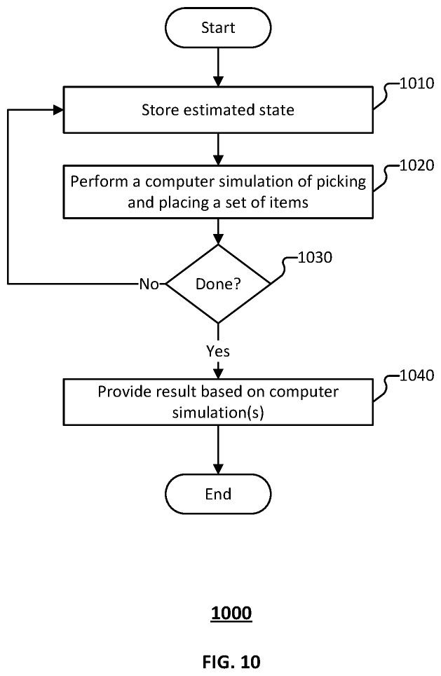

FIG. 10 is a flow diagram illustrating a process of using an estimated state in connection with simulation of moving a set of items according to various embodiments. In some embodiments, process 1000 is implemented at least in part by robotic system 100 of FIG. 1 and/or system 200 of FIG. 2.

At 1010, an estimated state is stored. The system stores an estimated state of a workspace, such as a geometric model of the workspace, or an estimated state determined based on a combination of the geometric model and sensor data captured by a vision system.

At 1020, a computer simulation of picking and placing a set of items is performed. The system performs the computer simulation of picking and placing items based at least in part on a selected state estimation model (e.g., based on selection of one or more characteristics or configurations, such as a stacking model, a noise profile, an order of placing the items, etc.).

At 1030, a determination is made as to whether the computer simulation(s) are complete. In response to determining that one or more further computer simulations are to be performed at 1030, process 1000 proceeds to 1010 at which 1010-1030 are iterated until all corresponding computer simulations have been performed. In response to determining that no further computer simulations are to be performed at 1030, process 1000 proceeds to 1040.

At 1040, a result based on the computer simulation(s) is provided. In some embodiments, the providing the result comprises determining a state estimation model that yields the best results (e.g., the best state estimation model), and providing an indication of the state estimation model that yields the best results (or one or more characteristics or configurations for such state estimation model).

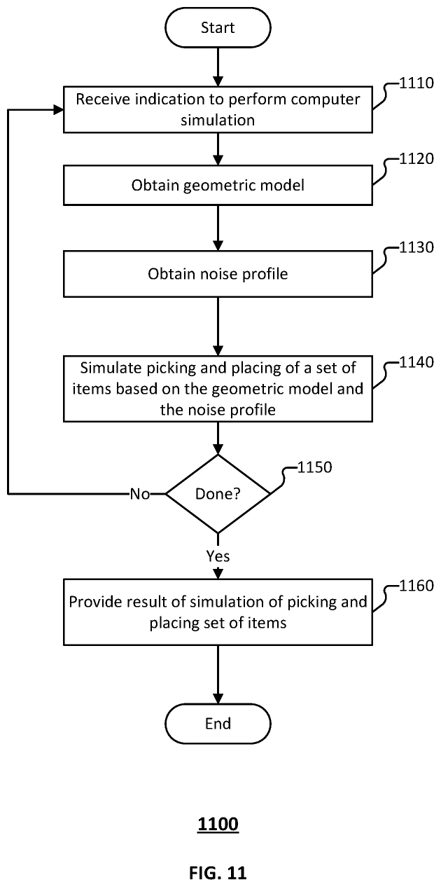

FIG. 11 is a flow diagram illustrating a process of performing a simulation of moving a set of items according to various embodiments. In some embodiments, process 1100 is implemented at least in part by robotic system 100 of FIG. 1 and/or system 200 of FIG. 2.

At 1110, an indication to perform a computer simulation is received.

At 1120, a geometric model is obtained.

At 1130, a noise profile is obtained. The noise profile is obtained based at least in part on the system determining the noise profile(s) that are expected to impact the picking and placing of items (e.g., determining corresponding expected sources of noise, etc.).

At 1140, a picking and placing of a set of items is simulated based at least in part on the geometric model and the noise profile.

In some embodiments, the system may model an adjustment that compensates for the noise. The system may determine the adjustment to be implemented with respect to the estimated state (e.g., the geometric model and/or sensor data) based at least in part on an expected noise (e.g., an expected type of noise and/or an expected extent of such noise, etc.).

At 1150, a determination is made as to whether process 1100 is complete. In some embodiments, process 1000 is determined to be complete in response to a determination that no further simulations are to be performed, a user has exited the system, an administrator indicates that process 1100 is to be paused or stopped, etc. In response to a determination that process 1100 is complete, process 1100 ends. In response to a determination that process 1100 is not complete, process 1100 returns to 1110.

At 1160, a result of the simulation of the picking and placing of the set of items is provided. In some embodiments, the providing the result comprises determining a state estimation model that yields the best results (e.g., the best state estimation model), and providing an indication of the state estimation model that yields the best results (or one or more characteristics or configurations for such state estimation model).

Although the foregoing examples are described in the context of palletizing or de-palletizing a set of items, various embodiments may be implemented in connection with singulating a set of items and/or kitting a set of items. For example, various embodiments are implemented to determine/estimate a state of the workspace (e.g., chute, conveyor, receptacle, etc.) based at least in part on geometric data and sensor data (e.g., a combination of the geometric data and sensor data, such as an interpolation between the geometric data and sensor data).

Various examples of embodiments described herein are described in connection with flow diagrams. Although the examples may include certain steps performed in a particular order, according to various embodiments, various steps may be performed in various orders and/or various steps may be combined into a single step or in parallel.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A robotic system, comprising:
a memory configured to store estimated state information associated with a computer simulation of a robotic operation to stack a plurality of items on a pallet or other receptacle; and
one or more processors coupled to the memory and configured to perform the computer simulation;
wherein:
the computer simulation is performed at least in part by combining geometric model data based on idealized simulated robotic placement of each item with programmatically generated noise data; and
the programmatically generated noise data reflects an estimation of the effect that one or more sources of noise in a real world physical workspace with which the computer simulation is associated would have on a real world state of one or both of the plurality of items and the pallet or other receptacle if the plurality of items were stacked on the pallet is or other receptacle as simulated in the computer simulation.

2. The robotic system of claim 1, wherein the computer simulation is one of a plurality of computer simulations performed by the one or more processors.

3. The robotic system of claim 2, wherein at least a plurality of the computer simulations run in parallel.

4. The robotic system of claim 2, wherein each of the plurality of computer simulations are based on a different planning algorithm.

5. The robotic system of claim 2, wherein each of the plurality of computer simulations are based on a different stacking algorithm.

6. The robotic system of claim 2, wherein each of the plurality of computer simulations implement a same planning or stacking algorithm, and each of the plurality of simulations implement a different order or placement of items.

7. The robotic system of claim 2, wherein each of the plurality of computer simulations implement a different state estimation model from among a plurality of state estimation models.

8. The robotic system of claim 7, wherein each state estimation model of the plurality of state estimation models differently simulate the noise data.

9. The robotic system of claim 7, wherein each of the plurality of computer simulations implement a same state estimate model, and each of the plurality of computer simulations implement different settings or configurations.

10. The robotic system of claim 1, wherein the noise data reflects a miscalibration or misalignment of sensors comprised in a workspace comprising the plurality of items stacked on the pallet or other receptacle.

11. The robotic system of claim 1, wherein the noise data reflects environmental conditions of a workspace comprising the plurality of items stacked on the pallet or other receptacle.

12. The robotic system of claim 11, wherein the environmental conditions comprise one or more of dust, reflective surface glare, and humidity.

13. The robotic system of claim 1, wherein the noise data reflects an error with respect to item position.

14. The robotic system of claim 13, wherein the error with respect to item position is a deviation of a location of the item in a workspace relative to an expected location.

15. The robotic system of claim 14, wherein the deviation is caused by the item being pushed as a robotic arm places another item on a stack of items on the pallet or other receptacle.

16. The robotic system of claim 1, wherein the noise data is introduced based at least in part on:
generating a geometric pallet and a stack of items; and
applying the noise data to the generated geometric pallet and stack of items.

17. The robotic system of claim 16, wherein the noise data is non-linear.

18. The robotic system of claim 16, wherein the noise data is not uniformly distributed.

19. The robotic system of claim 16, wherein the noise data reflects imperfections introduced by a camera in the real world physical workspace.

20. The robotic system of claim 1, wherein the one or more processors iteratively run simulations with respect to one or more of (i) a plurality of state estimation models, and (ii) adjusting one or more parameters of a particular state estimation model.

21. The robotic system of claim 20, wherein the one or more processors implement a machine learning process to learn one or more characteristics or configurations that yields a best result.

22. The robotic system of claim 21, wherein the best result corresponds to a set of characteristics or configurations that provide a quickest estimation of the state given the noise data.

23. A method to control a robot, comprising:
storing estimated state information associated with a computer simulation of a robotic operation to stack a plurality of items on a pallet or other receptacle; and
performing, by one or more processors, the computer simulation;
wherein:
the computer simulation is performed at least in part by combining geometric model data based on idealized simulated robotic placement of each item with programmatically generated noise data; and
the programmatically generated noise data reflects an estimation of the effect that one or more sources of noise in a real world physical workspace with which the computer simulation is associated would have on a real world state of one or both of the plurality of items and the pallet or other receptacle if the plurality of items were stacked on the pallet or other receptacle as simulated in the computer simulation.

24. A computer program product to control a robot, the computer program product being embodied in a non-transitory computer readable medium and comprising computer instructions for:
storing estimated state information associated with a computer simulation of a robotic operation to stack a plurality of items on a pallet or other receptacle; and
performing, by one or more processors, the computer simulation;
wherein:
the computer simulation is performed at least in part by combining geometric model data based on idealized simulated robotic placement of each item with programmatically generated noise data; and
the programmatically generated noise data reflects an estimation of the effect that one or more sources of noise in a real world physical workspace with which the computer simulation is associated would have on a real world state of one or both of the plurality of items and the pallet or other receptacle if the plurality of items were stacked on the pallet or other receptacle as simulated in the computer simulation.
